(19) United States
(12) Patent Application Publication
(10) Pub. No.: US 2025/0356900 A1
(43) Pub. Date: Nov. 20, 2025

(54) Local-Bank-Level Scheduling of Usage-Based-Disturbance Mitigation Strategies Based on Global-Bank-Level Control

(71) Applicant: Micron Technology, Inc., Boise, ID (US)

(72) Inventor: Yang Lu, Boise, ID (US)

(73) Assignee: Micron Technology, Inc., Boise, ID (US)

(21) Appl. No.: 19/081,653

(22) Filed: Mar. 17, 2025

Related U.S. Application Data
(60) Provisional application No. 63/649,126, filed on May 17, 2024.

(51) Int. Cl. G11C 11/406

(52) U.S. Cl. CPC G11C 11/40622; G11C 11/40603; G11C 11/40615

(57) ABSTRACT

Apparatuses and techniques for local-bank-level scheduling enhancement of usage-based-disturbance mitigation based on global-bank-level control are described. To enable efficient utilization of timing resources, a memory device includes a refresh control circuit implemented at a global-bank level of the memory die and a mitigation decision circuit implemented at a local-bank level of the memory die. The refresh control circuit determines currently available timing resources for mitigating usage-based disturbance and generates a control signal to pass this information to the mitigation decision circuit. The mitigation decision circuit schedules the mitigation actions to efficiently utilize the currently available timing resources and ensure that different conditions associated with usage-based-disturbance are mitigated in order of priority. In this manner, available timing resources are efficiently utilized to decrease a risk of the memory device being subjected to usage-based disturbance. Furthermore, these techniques can be performed without significantly increasing cost or die size.

### CROSS-REFERENCE TO RELATED APPLICATION(S)

This application claims the benefit of U.S. Provisional Patent Application Ser. No. 63/649,126, filed on May 17, 2024, the disclosure of which is incorporated by reference herein in its entirety.

### BACKGROUND

Computers, smartphones, and other electronic devices rely on processors and memories. A processor executes code based on data to run applications and provide features to a user. The processor obtains the code and the data from a memory. The memory in an electronic device can include volatile memory (e.g., random-access memory (RAM)) and non-volatile memory (e.g., flash memory). Like the capabilities of a processor, the capabilities of a memory can impact the performance of an electronic device. This performance impact can increase as processors are developed that execute code faster and as applications operate on increasingly larger data sets that require ever-larger memories.

### BRIEF DESCRIPTION OF THE DRAWINGS

Apparatuses of and techniques for local-bank-level scheduling of usage-based-disturbance mitigation strategies based on global-bank-level control are described with reference to the following drawings. The same numbers are used throughout the drawings to reference like features and components:

FIG. 1 illustrates example apparatuses that can implement aspects of local-bank-level scheduling of usage-based-disturbance mitigation strategies based on global-bank-level control;

FIG. 2 illustrates an example computing system that can implement aspects of local-bank-level scheduling of usage-based-disturbance mitigation strategies based on global-bank-level control;

FIG. 3 illustrates example data stored within rows of a memory array;

FIG. 4 illustrates an example memory device in which aspects of local-bank-level scheduling of usage-based-disturbance mitigation strategies based on global-bank-level control can be implemented;

FIG. 5 illustrates an example arrangement of circuits that can implement aspects of local-bank-level scheduling of usage-based-disturbance mitigation strategies based on global-bank-level control;

FIG. 6 illustrates aspects of an example refresh command;

FIG. 7-1 illustrates a first example implementation of a usage-based-disturbance circuit;

FIG. 7-2 illustrates a second example implementation of a usage-based-disturbance circuit;

FIG. 8 illustrates example mitigation strategies for different conditions associated with usage-based disturbance;

FIG. 9 illustrates an example scheme performed by a usage-based-disturbance circuit;

FIG. 10 illustrates an example implementation of a die in which aspects of local-bank-level scheduling of usage-based-disturbance mitigation strategies based on global-bank-level control can be implemented;

FIG. 11 illustrates an example scheme implemented by a mitigation decision circuit for implementing aspects of local-bank-level scheduling of usage-based-disturbance mitigation strategies based on global-bank-level control.

FIG. 12 illustrates another example implementation of a die in which aspects of local-bank-level scheduling of usage-based-disturbance mitigation strategies based on global-bank-level control can be implemented;

FIG. 13 illustrates an example signal timing diagram for performing aspects of local-bank-level scheduling of usage-based-disturbance mitigation strategies based on global-bank-level control can be implemented; and

FIG. 14 illustrates an example method for implementing aspects of local-bank-level scheduling of usage-based-disturbance mitigation strategies based on global-bank-level control.

### DETAILED DESCRIPTION

### Overview

Processors and memory work in tandem to provide features to users of computers and other electronic devices. As processors and memory operate more quickly together in a complementary manner, an electronic device can provide enhanced features, such as high-resolution graphics and artificial intelligence (AI) analysis. Some applications, such as those for financial services, medical devices, and advanced driver assistance systems (ADAS), can also demand more-reliable memories. These applications use increasingly reliable memories to limit errors in financial transactions, medical decisions, and object identification. However, in some implementations, more-reliable memories can sacrifice bit densities, power efficiency, and simplicity.

To meet the demands for physically smaller memories, memory devices can be designed with higher chip densities. Increasing chip density, however, can increase the electromagnetic coupling (e.g., capacitive coupling) between adjacent or proximate rows of memory cells due, at least in part, to a shrinking distance between these rows. With this undesired coupling, activation (or charging) of a first row of memory cells can sometimes negatively impact a second nearby row of memory cells. In particular, activation of the first row can generate interference, or crosstalk, that causes the second row to experience a voltage fluctuation. In some instances, this voltage fluctuation can cause a state (or value) of a memory cell in the second row to be incorrectly determined by a sense amplifier. Consider an example in which a state of a memory cell in the second row is a “1,” In this example, the voltage fluctuation can cause a sense amplifier to incorrectly determine the state of the memory cell to be a “0” instead of a “1.” Left unchecked, this interference can lead to memory errors or data loss within the memory device.

In some circumstances, a particular row of memory cells is activated repeatedly in an unintentional or intentional (sometimes malicious) manner. Consider, for instance, that memory cells in an R^{th} row are subjected to repeated activation, which causes one or more memory cells in an adjacent row (e.g., within an R+1 row, an R+2 row, an R−1 row, and/or an R−2 row) to change states. This effect is referred to as usage-based disturbance. The occurrence of usage-based disturbance can lead to the corruption or changing of contents within the affected row of memory.

Memory devices store data using memory cells. Each memory cell can leak charge over time, which can cause the memory device to lose data. To avoid this issue, the memory device periodically refreshes the charge on the memory cells. As memory devices are designed with larger storage capacities, timing resources can become constrained for refreshing larger quantities of memory cells. The limited timing resources for performing refreshes and the increased quantities of memory cells can add further challenges to mitigating usage-based disturbance. As memory devices increase in size, there is a need to ensure that the timing resources available for mitigating usage-based disturbance are efficiently utilized.

To address this and other issues regarding usage-based disturbance, this document describes techniques for local-bank-level scheduling of usage-based-disturbance mitigation strategies based on global-bank-level control. In an example aspect, a usage-based-disturbance circuit implemented at a local-bank level of a memory die is capable of detecting different conditions associated with usage-based disturbance. This usage-based-disturbance circuit is also capable of supporting different mitigation strategies that utilize different amounts of a timing resource to mitigate the different conditions.

To enable efficient utilization of timing resources, the memory device also includes a refresh control circuit implemented at a global-bank level of the memory die and a mitigation decision circuit implemented at the local-bank level. The refresh control circuit determines currently available timing resources for mitigating usage-based disturbance and generates a control signal to pass this information to the mitigation decision circuit. The mitigation decision circuit enhances the scheduling of the mitigation strategies to efficiently utilize the currently available timing resources and ensure that the different conditions are mitigated in an order of priority. In this manner, available timing resources are efficiently utilized to decrease a risk of the memory device being subjected to usage-based disturbance. Furthermore, these techniques can be performed without significantly increasing cost or die size.

A communication interface between the refresh control circuit and the mitigation decision circuit can be designed in such a way as to be readily adaptable for supporting different types and/or different quantities of mitigation strategies. In example implementations, the communication between the refresh control circuit and the mitigation decision circuit is one-way in which the refresh control circuit functions as a traffic light (or multiple traffic lights) to enable the mitigation decision circuit to determine which mitigation strategies can be performed with the available timing resources. In addition to reducing (e.g., minimizing) the amount of signal routing between the global-bank level and the local-bank level, this type of communication interface is flexible in supporting a variety of techniques that are implemented at the local-bank level for mitigating usage-based disturbance.

### Example Operating Environments

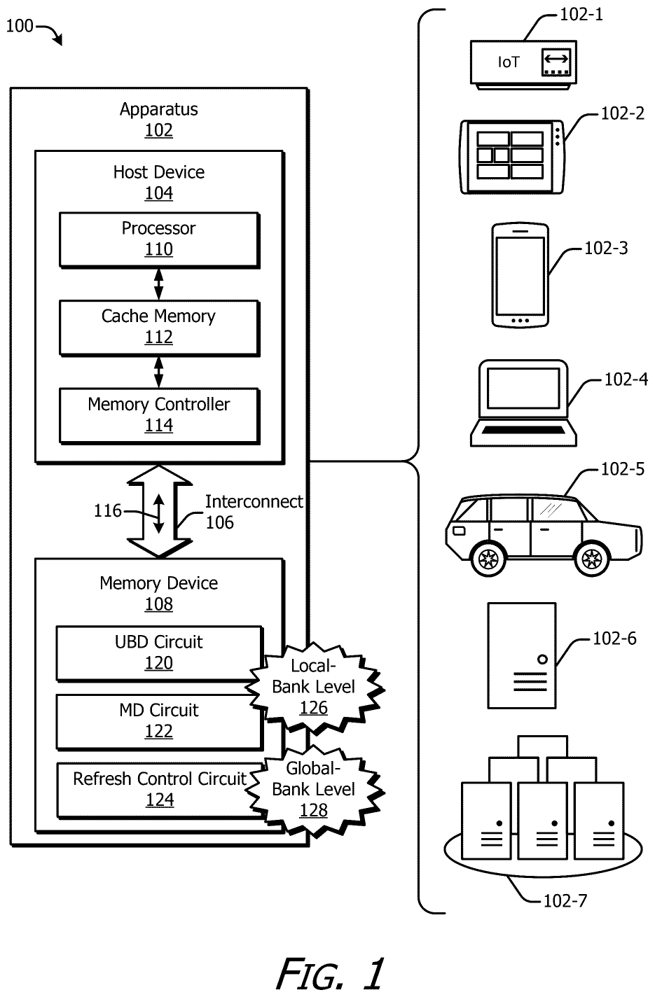

FIG. 1 illustrates, at 100 generally, an example operating environment including an apparatus 102 that can implement aspects of local-bank-level scheduling of usage-based-disturbance mitigation strategies based on global-bank-level control. The apparatus 102 can include various types of electronic devices, including an internet-of-things (IoT) device 102-1, tablet device 102-2, smartphone 102-3, notebook computer 102-4, passenger vehicle 102-5, server computer 102-6, and server cluster 102-7 that may be part of cloud computing infrastructure, a data center, or a portion thereof (e.g., a printed circuit board (PCB)). Other examples of the apparatus 102 include a wearable device (e.g., a smartwatch or intelligent glasses), entertainment device (e.g., a set-top box, video dongle, smart television, a gaming device), desktop computer, motherboard, server blade, consumer appliance, vehicle, drone, industrial equipment, security device, sensor, or the electronic components thereof. Each type of apparatus can include one or more components to provide computing functionalities or features.

In example implementations, the apparatus 102 can include at least one host device 104, at least one interconnect 106, and at least one memory device 108. The host device 104 can include at least one processor 110, at least one cache memory 112, and a memory controller 114. The memory device 108, which can also be realized with a memory module, can include, for example, a dynamic random-access memory (DRAM) die or module (e.g., Low-Power Double Data Rate synchronous DRAM (LPDDR SDRAM)). The DRAM die or module can include a three-dimensional (3D) stacked DRAM device, which may be a high-bandwidth memory (HBM) device or a hybrid memory cube (HMC) device. The memory device 108 can operate as a main memory for the apparatus 102. Although not illustrated, the apparatus 102 can also include storage memory. The storage memory can include, for example, a storage-class memory device (e.g., a flash memory, hard disk drive, solid-state drive, phase-change memory (PCM), or memory employing 3D XPoint™).

The processor 110 is operatively coupled to the cache memory 112, which is operatively coupled to the memory controller 114. The processor 110 is also coupled, directly or indirectly, to the memory controller 114. The host device 104 may include other components to form, for instance, a system-on-a-chip (SoC). The processor 110 may include a general-purpose processor, central processing unit, graphics processing unit (GPU), neural network engine or accelerator, application-specific integrated circuit (ASIC), field-programmable gate array (FPGA) integrated circuit (IC), or communications processor (e.g., a modem or baseband processor).

In operation, the memory controller 114 can provide a high-level or logical interface between the processor 110 and at least one memory (e.g., an external memory). The memory controller 114 may be realized with any of a variety of suitable memory controllers (e.g., a double-data-rate (DDR) memory controller that can process requests for data stored on the memory device 108). Although not shown, the host device 104 may include a physical interface (PHY) that transfers data between the memory controller 114 and the memory device 108 through the interconnect 106. For example, the physical interface may be an interface that is compatible with a DDR PHY Interface (DFI) Group interface protocol. The memory controller 114 can, for example, receive memory requests from the processor 110 and provide the memory requests to external memory with appropriate formatting, timing, and reordering. The memory controller 114 can also forward to the processor 110 responses to the memory requests received from external memory.

The host device 104 is operatively coupled, via the interconnect 106, to the memory device 108. In some examples, the memory device 108 is connected to the host device 104 via the interconnect 106 with an intervening buffer or cache. The memory device 108 may operatively couple to storage memory (not shown). The host device 104 can also be coupled, directly or indirectly via the interconnect 106, to the memory device 108 and the storage memory. The interconnect 106 and other interconnects (not illustrated in FIG. 1) can transfer data between two or more components of the apparatus 102. Examples of the interconnect 106 include a bus (e.g., a unidirectional or bidirectional bus), switching fabric, or one or more wires that carry voltage or current signals. The interconnect 106 can propagate one or more communications 116 between the host device 104 and the memory device 108. For example, the host device 104 may transmit a memory request to the memory device 108 over the interconnect 106. Also, the memory device 108 may transmit a corresponding memory response to the host device 104 over the interconnect 106.

The illustrated components of the apparatus 102 represent an example architecture with a hierarchical memory system. A hierarchical memory system may include memories at different levels, with each level having memory with a different speed or capacity. As illustrated, the cache memory 112 logically couples the processor 110 to the memory device 108. In the illustrated implementation, the cache memory 112 is at a higher level than the memory device 108. A storage memory, in turn, can be at a lower level than the main memory (e.g., the memory device 108). Memory at lower hierarchical levels may have a decreased speed but increased capacity relative to memory at higher hierarchical levels.

The apparatus 102 can be implemented in various manners with more, fewer, or different components. For example, the host device 104 may include multiple cache memories (e.g., including multiple levels of cache memory) or no cache memory. In other implementations, the host device 104 may omit the processor 110 or the memory controller 114. A memory (e.g., the memory device 108) may have an “internal” or “local” cache memory. As another example, the apparatus 102 may include cache memory between the interconnect 106 and the memory device 108. Computer engineers can also include any of the illustrated components in distributed or shared memory systems.

Computer engineers may implement the host device 104 and the various memories in multiple manners. In some cases, the host device 104 and the memory device 108 can be disposed on, or physically supported by, a printed circuit board (e.g., a rigid or flexible motherboard). The host device 104 and the memory device 108 may additionally be integrated together on an integrated circuit or fabricated on separate integrated circuits and packaged together. The memory device 108 may also be coupled to multiple host devices 104 via one or more interconnects 106 and may respond to memory requests from two or more host devices 104. Each host device 104 may include a respective memory controller 114, or the multiple host devices 104 may share a memory controller 114. This document describes with reference to FIG. 1 an example computing system architecture having at least one host device 104 coupled to a memory device 108.

Two or more memory components (e.g., modules, dies, banks, or bank groups) can share the electrical paths or couplings of the interconnect 106. The interconnect 106 can include at least one command-and-address bus (CA bus) and at least one data bus (DQ bus). The command-and-address bus can transmit addresses and commands from the memory controller 114 of the host device 104 to the memory device 108, which may exclude propagation of data. The data bus can propagate data between the memory controller 114 and the memory device 108. The memory device 108 may also be implemented as any suitable memory including, but not limited to, DRAM, SDRAM, three-dimensional (3D) stacked DRAM, DDR memory, or LPDDR memory (e.g., LPDDR DRAM or LPDDR SDRAM).

The memory device 108 can form at least part of the main memory of the apparatus 102. The memory device 108 may, however, form at least part of a cache memory, a storage memory, or a system-on-chip of the apparatus 102. The memory device 108 includes at least one instance of usage-based-disturbance circuit 120 (UBD circuit 120), at least one mitigation decision circuit 122 (MD circuit 122), and at least one refresh control circuit 124. The usage-based-disturbance circuit 120, the mitigation decision circuit 122, and the refresh control circuit 124 can each be implemented using software, firmware, hardware, fixed logic circuitry, or some combinations thereof. The mitigation decision circuit 122 can be integrated within the usage-based-disturbance circuit 120 or can be considered separate from the usage-based-disturbance circuit 120.

The usage-based-disturbance circuit 120 mitigates usage-based disturbance for one or more banks associated with the memory device 108. This includes detecting a condition associated with usage-based disturbance and initiating a refresh of one or more victim rows associated with the detected condition. The usage-based-disturbance circuit 120 can employ various strategies for detecting and mitigating usage-based disturbance conditions. Example implementations of the usage-based-disturbance circuit 120 are further described with respect to FIGS. 7-1 and 7-2.

The mitigation decision circuit 122 acts as an interface between the refresh control circuit 124 and the usage-based-disturbance circuit 120. The mitigation decision circuit 122 controls the scheduling of actions performed by the usage-based-disturbance circuit 120 to effectively utilize available timing resources. An example implementation of the mitigation decision circuit 122 can be implemented using logic gates. The mitigation decision circuit 122 can optionally be referred to as a mitigation optimization circuit or a prioritization circuit.

The refresh control circuit 124 determines currently available timing resources for mitigating usage-based disturbance and communicates this information to the mitigation decision circuit 122. The available timing resources can represent a quantity of refreshes (e.g., a quantity of refresh pumps or quantity of refresh pulses) that are available for mitigating usage-based-disturbance conditions and are associated with a current refresh command.

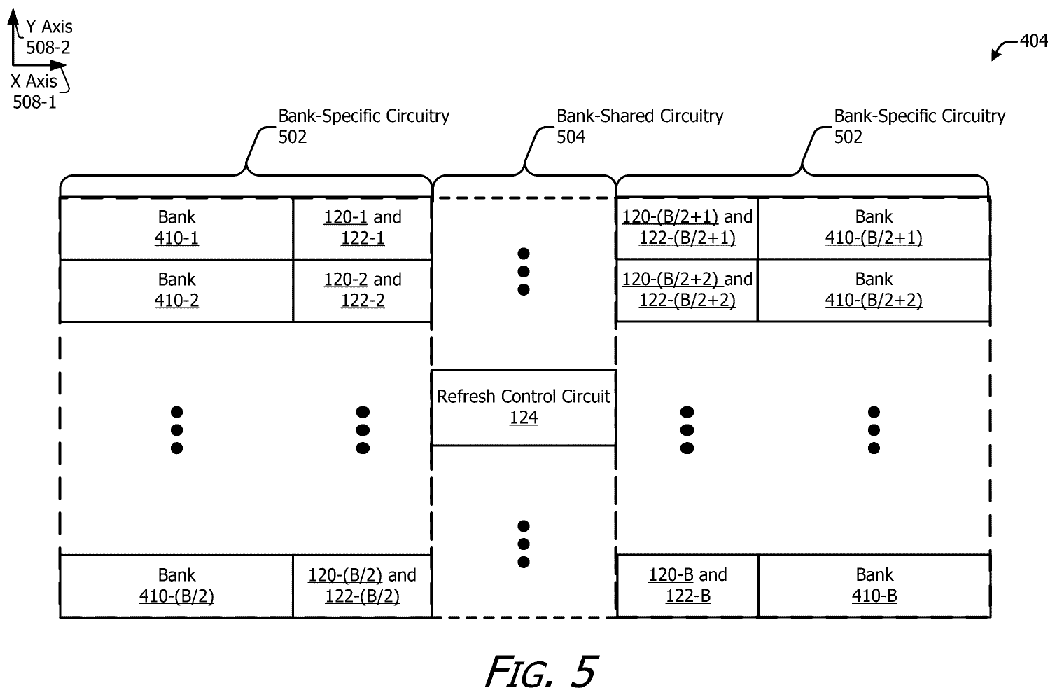

In example implementations, the usage-based-disturbance circuit 120 and the mitigation decision circuit 122 are implemented at a local-bank level 126 (or a local level). This means that each instance of the usage-based-disturbance circuit 120 and each instance of the mitigation decision circuit 122 is associated with a particular bank or a particular set of banks. In contrast, the refresh control circuit 124 is implemented at a global-bank level 128 (e.g., a global level or a central level). This means that one instance of the refresh control circuit 124 implemented at the global-bank level 128 can interface with two or more mitigation decision circuits 122 that are implemented at the local-bank level 126. The relationship between the local-bank level 126 and the global-bank level 128 is further described with respect to FIG. 5.

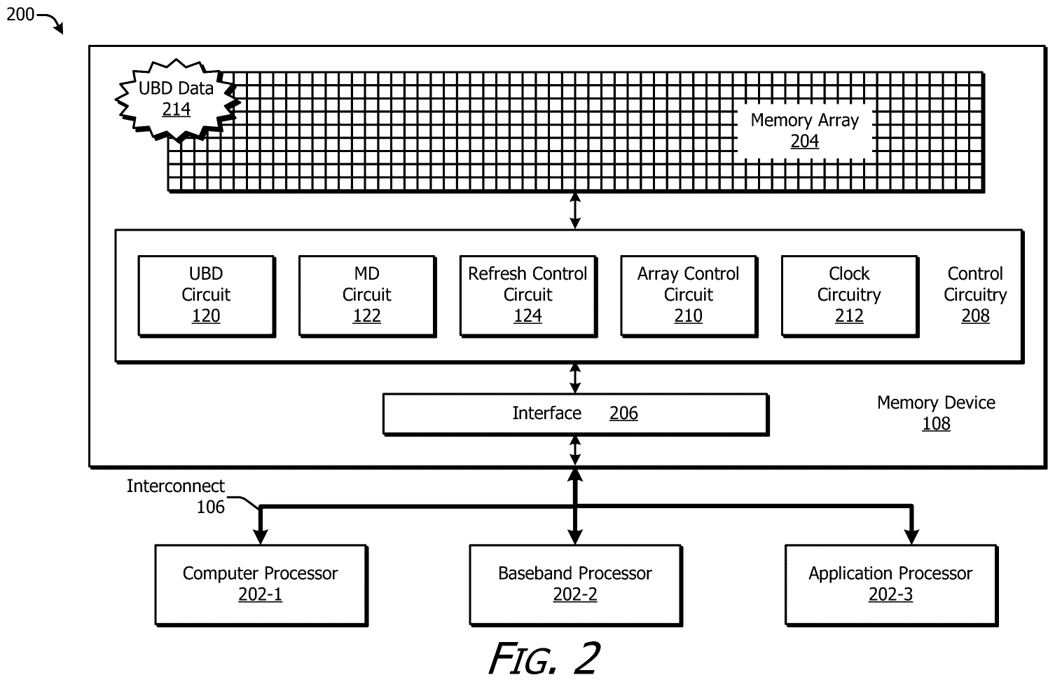

To simplify communications between the refresh control circuit 124 and the mitigation decision circuit 122, the refresh control circuit 124 provides the global-bank-level control while the mitigation decision circuit 122 provides the local-bank-level scheduling for performing usage-based-disturbance mitigation. In some example implementations, the refresh control circuit 124 does not have access to information regarding the types of mitigation strategies that can be employed at the local-bank level 126 to mitigate usage-based disturbance. The refresh control circuit 124, however, does have information at the global-bank level 128 regarding the available timing resources associated with a current refresh command. With this information, the refresh control circuit 124 functions as a traffic light for the mitigation decision circuit 122. As a traffic light can control whether or not traffic can proceed through an intersection, the refresh control circuit 124 can signal to control whether or not or how the mitigation decision circuit 122 schedules mitigation strategies. Furthermore, a traffic light can use different colored lights to provide a real-time indication of an amount of time that is remaining for traversing an intersection. In a similar way, the refresh control circuit 124 can provide a real-time indication of the amount of timing resources that remain available for mitigating usage-based-disturbance based on a current refresh command. Other components of the memory device 108 are further described with respect to FIG. 2.

FIG. 2 illustrates an example computing system 200 that can implement aspects of local-bank-level scheduling of usage-based-disturbance mitigation strategies based on global-bank-level control. In some implementations, the computing system 200 includes at least one memory device 108, at least one interconnect 106, and at least one processor 202. The memory device 108 can include, or be associated with, at least one memory array 204, at least one interface 206, and control circuitry 208 (or periphery circuitry) operatively coupled to the memory array 204. The memory array 204 can include an array of memory cells, including but not limited to memory cells of DRAM, SDRAM, three-dimensional (3D) stacked DRAM, DDR memory, LPDDR SDRAM, and so forth. The memory array 204 and the control circuitry 208 may be components on a single semiconductor die or on separate semiconductor dies. The memory array 204 or the control circuitry 208 may also be distributed across multiple dies. This control circuitry 208 may manage traffic on a bus that is separate from the interconnect 106.

The control circuitry 208 can include various components that the memory device 108 can use to perform various operations. These operations can include communicating with other devices, managing memory performance, performing refresh operations (e.g., self-refresh operations or auto-refresh operations), and performing memory read or write operations. In the depicted configuration, the control circuitry 208 includes the usage-based-disturbance circuit 120, the mitigation decision circuit 122, the refresh control circuit 124, at least one array control circuit 210, and at least one instance of clock circuitry 212. In some implementations, the usage-based-disturbance circuit 120, the mitigation decision circuit 122, and the refresh control circuit 124 are part of the control circuitry 208, as shown in FIG. 2. In other implementations, the usage-based-disturbance circuit 120, the mitigation decision circuit 122, the refresh control circuit 124, or some combination thereof are considered separate from the control circuitry 208.

The array control circuit 210 can include circuitry that provides command decoding, address decoding, input/output functions, amplification circuitry, power supply management, power control modes, and other functions. The clock circuitry 212 can synchronize various memory components with one or more external clock signals provided over the interconnect 106, including a command-and-address clock or a data clock. The clock circuitry 212 can also use an internal clock signal to synchronize memory components and may provide timer functionality.

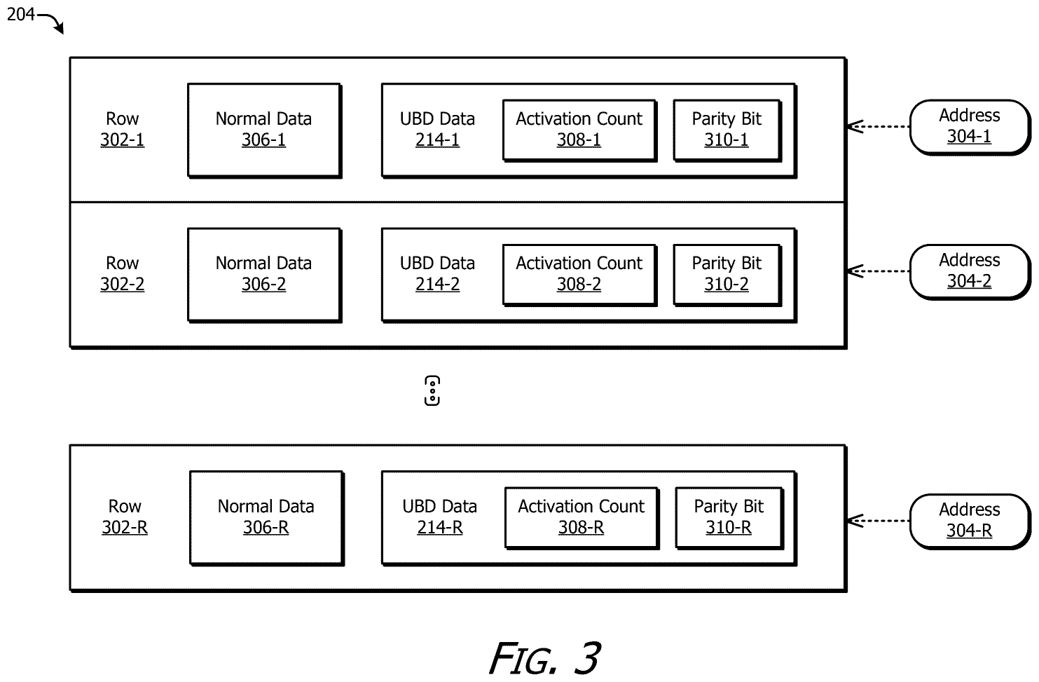

The usage-based-disturbance circuit 120 can be coupled to a set of memory cells within the memory array 204 that store usage-based-disturbance data 214 (UBD data 214). The usage-based-disturbance data 214 can include information such as an activation count, which represents a quantity of times one or more rows within the memory array 204 have been activated (or accessed) by the memory device 108. In example implementations, each row of the memory array 204 includes a subset of memory cells that stores the usage-based-disturbance data 214 associated with that row, as further described with respect to FIG. 3.

The interface 206 can couple the control circuitry 208 or the memory array 204 directly or indirectly to the interconnect 106. In some implementations, the usage-based-disturbance circuit 120, the mitigation decision circuit 122, the refresh control circuit 124, the array control circuit 210, and the clock circuitry 212 can be part of a single component (e.g., the control circuitry 208). In other implementations, one or more of the usage-based-disturbance circuit 120, the mitigation decision circuit 122, the refresh control circuit 124, the array control circuit 210, or the clock circuitry 212 may be implemented as separate components, which can be provided on a single semiconductor die or disposed across multiple semiconductor dies. These components may individually or jointly couple to the interconnect 106 via the interface 206.

The interconnect 106 may use one or more of a variety of interconnects that communicatively couple together various components and enable commands, addresses, or other information and data to be transferred between two or more components (e.g., between the memory device 108 and the processor 202). Although the interconnect 106 is illustrated with a single line in FIG. 2, the interconnect 106 may include at least one bus, at least one switching fabric, one or more wires or traces that carry voltage or current signals, at least one switch, one or more buffers, and so forth. Further, the interconnect 106 may be separated into at least a command-and-address bus and a data bus.

In some aspects, the memory device 108 may be a “separate” component relative to the host device 104 (of FIG. 1) or any of the processors 202. The separate components can include a printed circuit board, memory card, memory stick, and memory module (e.g., a single in-line memory module (SIMM) or dual in-line memory module (DIMM)). Thus, separate physical components may be located together within the same housing of an electronic device or may be distributed over a server rack, a data center, and so forth. Alternatively, the memory device 108 may be integrated with other physical components, including the host device 104 or the processor 202, by being combined on a printed circuit board or in a single package or a system-on-chip.

As shown in FIG. 2, the processors 202 may include a computer processor 202-1, a baseband processor 202-2, and an application processor 202-3, coupled to the memory device 108 through the interconnect 106. The processors 202 may include or form a part of a central processing unit, graphics processing unit, system-on-chip, application-specific integrated circuit, or field-programmable gate array. In some cases, a single processor can comprise multiple processing resources, each dedicated to different functions (e.g., modem management, applications, graphics, central processing). In some implementations, the baseband processor 202-2 may include or be coupled to a modem (not illustrated in FIG. 2) and referred to as a modem processor. The modem or the baseband processor 202-2 may be coupled wirelessly to a network via, for example, cellular, Wi-Fi®, Bluetooth®, near field, or another technology or protocol for wireless communication.

In some implementations, the processors 202 may be connected directly to the memory device 108 (e.g., via the interconnect 106). In other implementations, one or more of the processors 202 may be indirectly connected to the memory device 108 (e.g., over a network connection or through one or more other devices). The memory array 204 is further described with respect to FIG. 3.

FIG. 3 illustrates example data stored within rows of the memory array 204. The memory array 204 includes multiple rows 302 of memory cells. For example, the memory array 204 depicted in FIG. 3 includes rows 302-1, 302-2 . . . 302-R, where R represents a positive integer. Each row 302 is associated with an address 304 (e.g., a row address, a memory row address, or a memory address). For example, the first row 302-1 has a first address 304-1, the second row 302-2 has a second address 304-2, and an R^{th} row 302-R has an R^{th} address 304-R.

Each of the rows 302 can store normal data 306 within a first subset of the memory cells associated with that row 302. The normal data 306 represents data that is read from or written to the memory device 108 during normal memory operations (e.g., during normal read or write operations). The normal data 306, for example, can include data that is transmitted by the memory controller 114 and is written to one or more rows 302 of the memory array 204.

In addition to the normal data 306, each of the rows 302 can store usage-based-disturbance data 214 within a second subset of the memory cells associated with that row 302. The usage-based-disturbance data 214 includes information that enables the usage-based-disturbance circuit 120 to mitigate usage-based disturbance. In an example implementation, the usage-based-disturbance data 214 includes an activation count 308. With the activation count 308, the memory device 108 can keep track of a quantity of accesses or activations of the corresponding memory row 302. In some example implementations, the usage-based-disturbance data 214 can also include a count of how many times a neighboring row (e.g., an adjacent or a proximate row) is refreshed in order to mitigate usage-based disturbance. Each of these counts provide an example means by which the memory device 108 can monitor for usage-based disturbance and determine when to refresh victim rows to reduce the risk of usage-based disturbance corrupting data.

In the example shown in FIG. 3, the first row 302-1 stores first normal data 306-1 within a first subset of memory cells of the first row 302-1 and stores first usage-based-disturbance data 214-1 within a second subset of memory cells of the first row 302-1. The first usage-based-disturbance data 214-1 includes a first activation count 308-1, which represents a quantity of times the first row 302-1 has been activated since a last refresh. As another example, the second row 302-2 stores second normal data 306-2 within a first subset of memory cells within the second row 302-2 and stores second usage-based-disturbance data 214-2 within a second subset of memory cells within the second row 302-2. The second usage-based-disturbance data 214-2 includes a second activation count 308-2, which represents a quantity of times the second row 302-2 has been activated since a last refresh. Additionally, the R^{th} row 302-R stores R^{th} normal data 306-R within a first subset of memory cells within the R^{th} row 302-R and stores R^{th} usage-based-disturbance data 214-R within a second subset of memory cells within the R^{th} row 302-R. The R^{th} usage-based-disturbance data 214-R includes an R^{th} activation count 308-R, which represents a quantity of times the R^{th} row 302-R has been activated since a last refresh.

The usage-based-disturbance data 214 can also include information or can be formatted (e.g., coded) in such a way as to support error detection. In this example, the usage-based-disturbance data 214 includes a parity bit 310. In particular, the usage-based-disturbance data 214-1, 214-2, and 214-R respectively includes parity bits 310-1, 310-2, and 310-R. Other implementations are also possible in which the usage-based-disturbance data 214 is coded in a manner that supports any of the error detection tests described above, such as the error-correcting-code check. Although the techniques for detecting a condition associated with usage-based disturbance is generally described with respect to the activation count 308, these techniques can generally be applied to detecting a condition based on any type of information that is represented by the usage-based-disturbance data 214, including error detection techniques.

### Example Techniques and Hardware

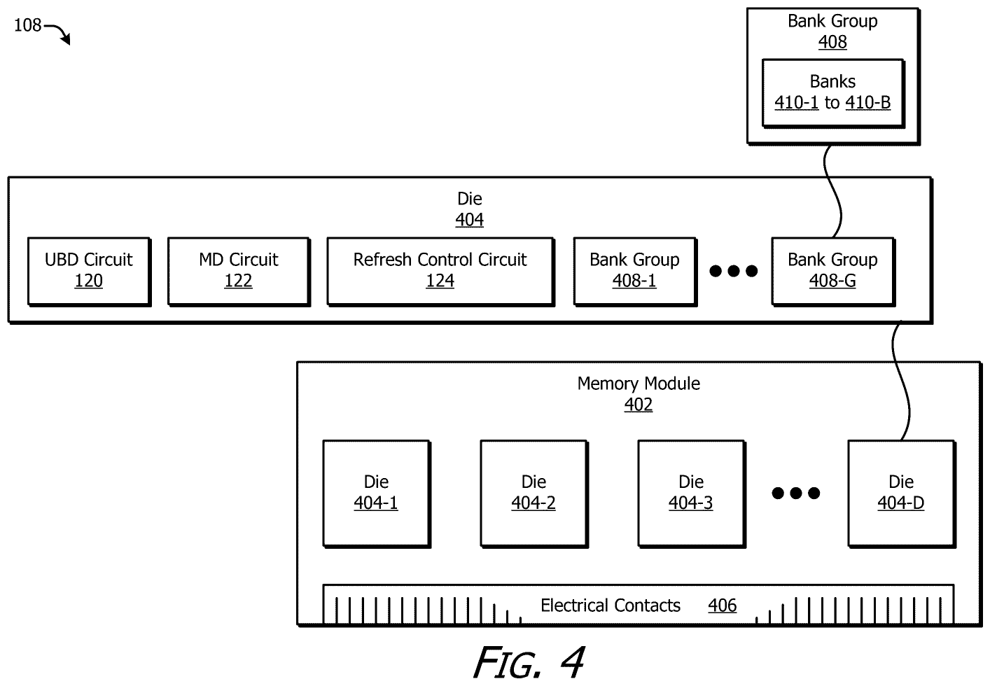

FIG. 4 illustrates an example memory device 108 in which aspects of local-bank-level scheduling of usage-based-disturbance mitigation strategies based on global-bank-level control can be implemented. The memory device 108 includes a memory module 402, which can include multiple dies 404. As illustrated, the memory module 402 includes a first die 404-1, a second die 404-2, a third die 404-3, and a D^{th} die 404-D, with D representing a positive integer. The memory module 402 can be a SIMM or a DIMM. As another example, the memory module 402 can interface with other components via a bus interconnect (e.g., a Peripheral Component Interconnect Express (PCIe®) bus). The memory device 108 illustrated in FIGS. 1 and 2 can correspond, for example, to multiple dies (or dice) 404-1 through 404-D, or a memory module 402 with two or more dies 404. As shown, the memory module 402 can include one or more electrical contacts 406 (e.g., pins) to interface the memory module 402 to other components.

The memory module 402 can be implemented in various manners. For example, the memory module 402 may include a printed circuit board, and the multiple dies 404-1 through 404-D may be mounted or otherwise attached to the printed circuit board. The dies 404 (e.g., memory dies) may be arranged in a line or along two or more dimensions (e.g., forming a grid or array). The dies 404 may have a similar size or may have different sizes. Each die 404 may be similar to another die 404 or different in size, shape, data capacity, or control circuitries. The dies 404 may also be positioned on a single side or on multiple sides of the memory module 402.

One or more of the dies 404-1 to 404-D include the usage-based-disturbance circuit 120, the mitigation decision circuit 122, the refresh control circuit 124, and bank groups 408-1 to 408-G, with G representing a positive integer. Each bank group 408 includes at least two banks 410, such as banks 410-1 to 410-B, with B representing a positive integer. In some implementations, the die 404 includes multiple instances of the usage-based-disturbance circuit 120, which mitigate usage-based disturbance across at least one of the banks 410. The die 404 also includes multiple instances of the mitigation decision circuit 122, which controls the scheduling of the mitigation actions performed by the usage-based-disturbance circuit 120. For example, multiple instances of the usage-based-disturbance circuit 120 can respectively mitigate usage-based disturbance across the bank groups 408-1 to 408-G. Also, multiple instances of the mitigation decision circuit 122 can respectively control the multiple instances of the usage-based-disturbance circuit 120.

In other implementations, multiple instances of the usage-based-disturbance circuit 120 can respectively mitigate usage-based disturbance for respective banks 410. In this case, each usage-based-disturbance circuit 120 mitigates usage-based disturbance for a single bank 410 within one of the bank groups 408-1 to 408-B. Also, each mitigation decision circuit 122 can control a corresponding one of the usage-based-disturbance circuit 120.

In yet other example implementations, each usage-based-disturbance circuit 120 mitigates usage-based disturbance for a subset of the banks 410 associated with one of the bank groups 408-1 to 408-G, where the subset of the banks 410 includes at least two banks 410. Also, each mitigation decision circuit 122 can control a corresponding one of the usage-based-disturbance circuit 120.

Various implementations of the refresh control circuit 124 are also possible. In a first example, the die 404 includes a single refresh control circuit 124 that is coupled to the one or more instances of the mitigation decision circuit 122. In a second example, the die 404 includes multiple refresh control circuit 124 that are coupled to respective sets of one or more mitigation decision circuits 122. The relationship between the banks 410-1 to 410-B, the usage-based-disturbance circuit 120, the mitigation decision circuit 122, and the refresh control circuit 124 are further described with respect to FIG. 5.

FIG. 5 illustrates an example arrangement of multiple instances of the usage-based-disturbance circuit 120 and multiple mitigation decision circuits 122 on a die 404. The die 404 includes bank-specific circuitry 502 and bank-shared circuitry 504. Bank-specific circuitry 502 includes components that are associated with a particular bank 410. For example, the bank-specific circuitry 502 includes the banks 410-1, 410-2 . . . 410-(B/2), 410-(B/2+1), 410-(B/2+2) . . . 410-B, the usage-based-disturbance circuit 120-1, 120-2 . . . 120-(B/2), 120-(B/2+1), 120-(B/2+2) . . . 120-B, and the mitigation decision circuits 122-1, 122-2 . . . 122-(B/2), 122-(B/2+1), 122-(B/2+2) . . . 122-B. The usage-based-disturbance circuit 120-1 to 120-B and the mitigation decision circuits 122-1 to 122-B are respectively coupled to the banks 410-1 to 410-B. In some cases, subsets of the banks 410-1 to 410-B are associated with different bank groups 408. In an example implementation, the die 404 includes 32 banks 410 (e.g., B equals 32). The 32 banks 410 form eight bank groups 408 (e.g., G equals 8), with each bank group 408 including four of the banks 410. In other cases, the banks 410-1 to 410-B are associated with a single bank group 408.

Each mitigation decision 122 can control a corresponding usage-based-disturbance circuit 120 to enhance scheduling for usage-based-disturbance mitigation. For example, the first mitigation decision circuit 122-1 can control the first usage-based-disturbance circuit 120-1 associated with the first bank 410-1. Likewise, the second mitigation decision circuit 122-2 can control the second usage-based-disturbance circuit 120-2 associated with the second bank 410-2.

The bank-shared circuitry 504 includes components that are associated with multiple banks 410. These components perform operations associated with multiple banks 410. Example components of the bank-shared circuitry 504 include the refresh control circuit 124.

On the die 404, the bank-specific circuitry 502 is positioned on two opposite sides of the bank-shared circuitry 504. Explained another way, the bank-shared circuitry 504 can be centrally positioned on the die 404. As such, the refresh control circuit 124 can be positioned closer to a center of the die 404 compared to the edges of the die 404. Positioning the bank-shared circuitry 504 in the center enables routing between the bank-shared circuitry 504 and the bank-specific circuitry 502 to be simplified.

Consider a first axis 508-1 (e.g., X axis 508-1) and a second axis 508-2 (e.g., Y axis 508-2), which is perpendicular to the first axis 508-1. In FIG. 5, the first axis 508-1 is depicted as a “horizontal” axis, and the second axis 508-2 is depicted as a “vertical” axis. Components of the bank-shared circuitry 504 are distributed across the second axis 508-2. A first set of the banks (e.g., banks 410-1 to 410-B/2) are arranged along the second axis 508-2 on a “left” side of the bank-shared circuitry 504, and a second set of the banks (e.g., banks 410-(B/2+1) to 410-B) are arranged along the second axis 508-2 on a “right” side of the bank-shared circuitry 504. The usage-based-disturbance circuit 120-1 to 120-B and the mitigation decision circuits 122-1 to 122-B are positioned between the corresponding banks 410-1 to 410-B and the bank-shared circuitry 504. By positioning the refresh control circuit 124 in a central location between the mitigation decision circuits 122-1 to 122-B, it can be easier to route signals between the refresh control circuit 124 and the mitigation decision circuits 122-1 to 122-B.

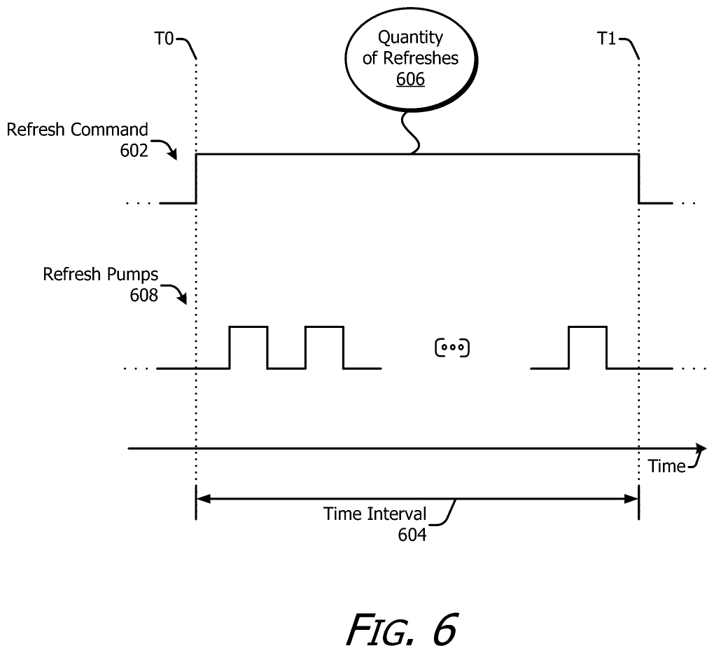

FIG. 6 illustrates an example refresh command 602, which can be received at the refresh control circuit 124. Between times T0 and T1, the refresh command 602 enables at least one row 302 within at least one bank 410 to be refreshed. In some cases, the refresh command 602 enables multiple rows 302 within a bank 410 to be refreshed. A time interval 604 associated with the refresh command 602 (e.g., the time between T0 and T1) enables a particular quantity of refreshes 606 to be performed in series or sequentially. The timing for performing a refresh is indicated (or controlled) by a refresh pump 608, which is generated by the refresh control circuit 124. The refresh pump 608 can alternatively be referred to as a refresh pulse. The term “refresh” can also be referred to as a row refresh or a refresh operation. Generally speaking, the quantity of refresh pumps 608 available for each refresh command 602 can vary depending on a duration of the time interval 604 and/or a refresh mode of the memory device 108.

Example types of refresh commands 602 can include a refresh management (RFM) command, a self-refresh command, an auto-refresh command, a normal refresh command, and/or can be any other command relating to refreshing at least one row 302 in the bank 410. Depending on the type of refresh command 602, some of the refresh pumps 608 associated with the refresh command 602 can be dedicated to normal refresh operations and thus are unavailable for mitigating usage-based disturbance. Additionally or alternatively, some or all of the refresh pumps 608 can be available for mitigating usage-based disturbance. It is also possible that some of the refresh pumps 608 associated with the refresh command 602 are previously-postponed refresh pumps 608. For the techniques described herein, the refresh command 602 is considered to have at least one refresh pump 608 that is available for mitigating usage-based disturbance.

To efficiently utilize available refresh pumps 608 for usage-based-disturbance mitigation, the refresh control circuit 124 and the mitigation decision circuit 122 communicate in a manner that enables one or more refreshes initiated by the usage-based-disturbance circuit 120 to be gated at the global-bank level 128 based on the available refresh pumps 608 and prioritized at the local-bank level 126 in a manner that complies with the gating. An operation of the usage-based-disturbance circuit 120 is further described with respect to FIGS. 7-1 to 9.

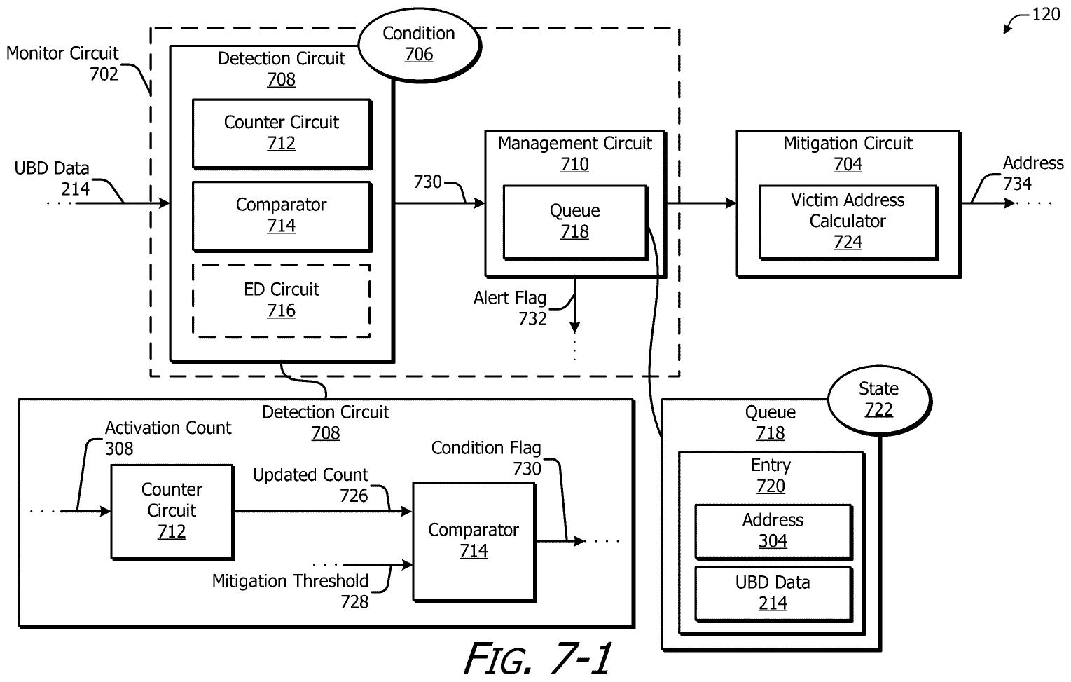

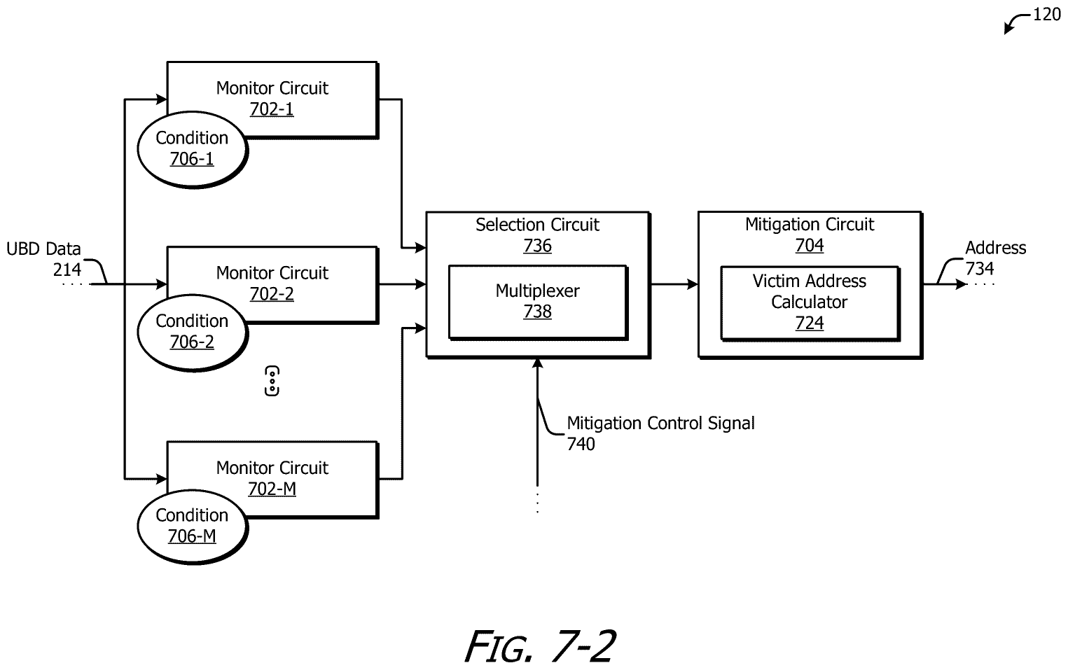

FIG. 7-1 illustrates an example implementation of the usage-based-disturbance circuit 120. In general, the usage-based-disturbance circuit 120 can detect one or more conditions (or events) that may lead to or indicate the presence of usage-based disturbance and mitigate its effects. To monitor for these conditions, the usage-based-disturbance circuit 120 maintains and updates the usage-based-disturbance data 214 that is stored in the memory array 204. If the usage-based-disturbance data 214 indicates that one of the conditions is present, then the related victim rows may be at increased risk for data corruption due to the usage-based-disturbance effect. To manage this risk, the usage-based-disturbance circuit 120 can support the refreshing of these victim rows.

In the depicted configuration, the usage-based-disturbance circuit 120 includes at least one monitor circuit 702 and at least one mitigation circuit 704. Although not explicitly shown, the monitor circuit 702 is coupled to the memory array 204. Through this coupling, the monitor circuit 702 can read the usage-based-disturbance data 214 associated with an activated row 302 and/or write updated usage-based-disturbance data 214 for the activated row 302. The mitigation circuit 704 is coupled between the monitor circuit 702 and other circuitry capable of performing a refresh, such as the control circuitry 208 or other refresh circuitry.

The monitor circuit 702 can detect a particular condition 706 associated with usage-based disturbance and monitor the detected condition 706 until it is mitigated. In some implementations, the usage-based-disturbance circuit 120 includes multiple monitor circuits 702, which detect different types of conditions 706 associated with usage-based disturbance as further described with respect to FIG. 7-2. The monitor circuit 702 includes at least one detection circuit 708 and at least one management circuit 710. The detection circuit 708 can be implemented using at least one counter circuit 712 and at least one comparator 714. The counter circuit 712 enables the detection circuit 708 to update the usage-based-disturbance data 214.

The detection circuit 708 can optionally include (or can optionally be coupled to) an error-detection circuit 716 (ED circuit 716). The error-detection circuit 716 can detect and/or correct bit errors associated with the usage-based-disturbance data 214. For example, the error-detection circuit 716 can perform a parity check based on the parity bit 310. The comparator 714, the error-detection circuit 716, or some combination thereof can be used to monitor for and detect one or more conditions 706 associated with usage-based disturbance. Other techniques are also possible in which the usage-based-disturbance circuit 120 uses another type of analysis-type circuit to monitor for and detect a condition 706. Other analysis-type circuits, for example, can analyze the activation of other neighboring rows or determine how often a neighboring row is refreshed due to usage-based-disturbance mitigation techniques.

The management circuit 710 keeps track of instances of a detected condition 706 that are to be mitigated once resources are available. In this example, the management circuit 710 includes at least one queue 718. The queue 718 can include one or more entries 720, which can store an address 304 of an aggressor row that is associated with an instance of the detected condition 706. In some cases, the entry 720 also includes the usage-based-disturbance data 214 that is related to the detected condition 706, such as the activation count 308 of the aggressor row.

The entries 720 within the queue 718 can be arranged and/or processed in a particular order, such as a first-in first-out (FIFO) order or a “worse case” order. In some cases, the priority-based order can be based on the activation count 308 such that higher-priority entries 720 have comparatively larger activation counts 308 as compared to those of lower-priority entries 720. In an example implementation, the queue 718 is implemented using content-addressable memory (CAM) or a plurality of registers. A size of the queue 718 (e.g., a quantity of entries 720 that can be stored) can vary depending on the implementation. In an example, the queue 718 can store up to 3, 5, or 10 entries 720.

In some implementations, the management circuit 710 can also monitor for one or more alert conditions and inform other components of the memory device 108 of a detected alert condition. Example alert conditions can be based on a state 722 of the queue 718 (e.g., a full state) or based on the usage-based-disturbance data 214. In an example implementation, the management circuit 710 determines whether an activation count 308 is greater than an alert threshold (e.g., determines whether the activation count 308 is approaching an intrinsic manufacturer limitation).

The mitigation circuit 704 initiates and/or performs an aspect of a mitigation procedure for a detected condition 706. An example mitigation procedure can include refreshing one or more rows 302 (e.g., one or more victim rows) that are impacted by the detected condition 706. It can also optionally include updating the usage-based-disturbance data 214, such as setting the usage-based-disturbance data 214 to a default state (e.g., setting the activation count 308 to a default value).

In this example, the mitigation circuit 704 includes at least one victim address calculator 724. The victim address calculator 724 identifies addresses of one or more victim rows that are to be refreshed based on an address 304 of an aggressor row. In some implementations, the victim rows that are determined by the victim address calculator 724 are based on the type of condition 706 that is detected by the monitor circuit 702. In other implementations, an operation of the victim address calculator 724 can be controlled by the memory controller 114. In this case, the victim address calculator 724 can be coupled to a register (not shown). By setting an operand of the register, the memory controller 114 can cause the victim address calculator 724 to identify victim rows based on one or more different methods.

Consider an example in which the aggressor row is represented by row R. In a first example, the victim address calculator 724 identifies the one or more victim rows to include one or more rows 302 that are immediately adjacent to the aggressor row (e.g., the R+1 and/or R−1 rows). In a second example, the victim address calculator 724 identifies the one or more victim rows to include one or more rows 302 that are proximate to the aggressor row but not immediately adjacent to the aggressor row (e.g., the R+2, R−2, R+3, and/or R−3 rows 302 or some combination thereof). In a third example, the victim address calculator 724 identifies one or more adjacent rows and one or more proximate but non-adjacent rows.

During operation, the memory device 108 activates a row 302. The monitor circuit 702 monitors the usage-based-disturbance data 214 associated with the activated row 302 to determine whether or not a condition 706 associated with usage-based disturbance is present. Consider an example implementation in which the detection circuit 708 reads and updates the usage-based-disturbance data 214 associated with the activated row 302. The counter circuit 712, for instance, accepts the activation count 308 associated with the activated row 302 and increments the activation count 308 to generate the updated count 726. The detection circuit 708 writes the updated count 726 back to the usage-based-disturbance data 214 that is associated with the activated row 302.

In this example, the condition 706 is associated with the activation count 308 meeting or exceeding a predetermined threshold. To monitor for the condition 706, the comparator 714 compares the updated count 726 to at least one mitigation threshold 728. If the updated count 726 is less than the mitigation threshold 728, the comparator 714 generates a condition flag 730 to indicate that the condition 706 is not present. In this case, the management circuit 710 does not take any further action.

If the updated count 726 is greater than or equal to the mitigation threshold 728, the comparator 714 generates the condition flag 730 to indicate that the condition 706 is present. In this case, the condition flag 730 causes the management circuit 710 to add an entry 720 within the queue 718 to store the address 304 of the activated row 302, which represents an aggressor row. The management circuit 710 also stores the usage-based-disturbance data 214 associated with the activated row 302 (e.g., the updated count 726) as part of the entry 720.

As time progresses, the management circuit 710 may detect an alert condition. In this case, the management circuit 710 generates an alert flag 732 to indicate the presence of the alert condition. The alert flag 732 can cause the memory device 108 to perform an alert-backoff (ABO) procedure. As part of the alert-backoff procedure, the memory device 108 pauses normal operations (e.g., normal read and/or write procedures requested by the host device 104) for a recovery period during which refresh management commands or other functions may be performed in the memory device 108 to mitigate usage-based disturbance. During this recovery period, the victim rows associated with the alert condition are refreshed.

When a refresh command 602 is issued and there are refresh pumps 608 available for mitigating usage-based disturbance, the mitigation circuit 704 can accept information regarding an entry 720 from the management circuit 710. Based on the address 304 of the aggressor row that caused the condition 706, the victim address calculator 724 determines addresses 734 of the one or more victim rows that are to be refreshed. The mitigation circuit 704 provides the one or more addresses 734 of the victim rows to other circuitry that performs the refresh.

As described above, the usage-based-disturbance circuit 120 can monitor for and detect a condition 706 associated with usage-based disturbance, keep track of the condition 706 until resources are available to refresh the victim rows, and initiate the mitigation procedure by providing the addresses 734 of the victim tows that are to be refreshed. Other implementations of the usage-based-disturbance circuit 120 are also possible in which the usage-based-disturbance circuit 120 monitors and detects multiple types of conditions 706 associated with usage-based disturbance, as further described with respect to FIG. 7-2.

FIG. 7-2 illustrates another example implementation of the usage-based-disturbance circuit 120. In the depicted configuration, the usage-based-disturbance circuit 120 includes multiple monitor circuits 702-1, 702-2 . . . 702-M, where M represents a positive integer. Each monitor circuit 702 can monitor a particular condition 706. For example, the monitor circuits 702-1, 702-2, and 702-M can respectively monitor for and detect conditions 706-1, 706-2, and 706-M.

In some implementations, the conditions 706 can be associated with different mitigation thresholds 728. In other implementations, the conditions 706 can be associated with a detected error in the usage-based-disturbance data 214 (e.g., a parity error or a coding error). Some conditions 706 can be determined based on the usage-based disturbance data 214 associated with the activated row 302. Other conditions 706 can be determined based on the usage-based-disturbance data 214 associated with one or more rows that are proximate to (and sometimes adjacent to) the activated row 302. In general, there are a variety of ways in which the monitor circuits 702-1 to 702-M can detect different conditions 706 associated with usage-based disturbance.

In this example implementation, the usage-based-disturbance circuit 120 also includes a selection circuit 736 along with the mitigation circuit 704. The selection circuit 736 is coupled between the multiple monitor circuits 702-1 to 702-M and the mitigation circuit 704. The selection circuit 736 enables one of the entries 720 associated with the detected conditions 706 to be passed from one of the monitor circuits 702-1 to 702-M to the mitigation circuit 704 for mitigation. In an example implementation, the selection circuit 736 is implemented using a multiplexer 738. Other implementations are also possible in which the selection circuit 736 is implemented using one or more switches.

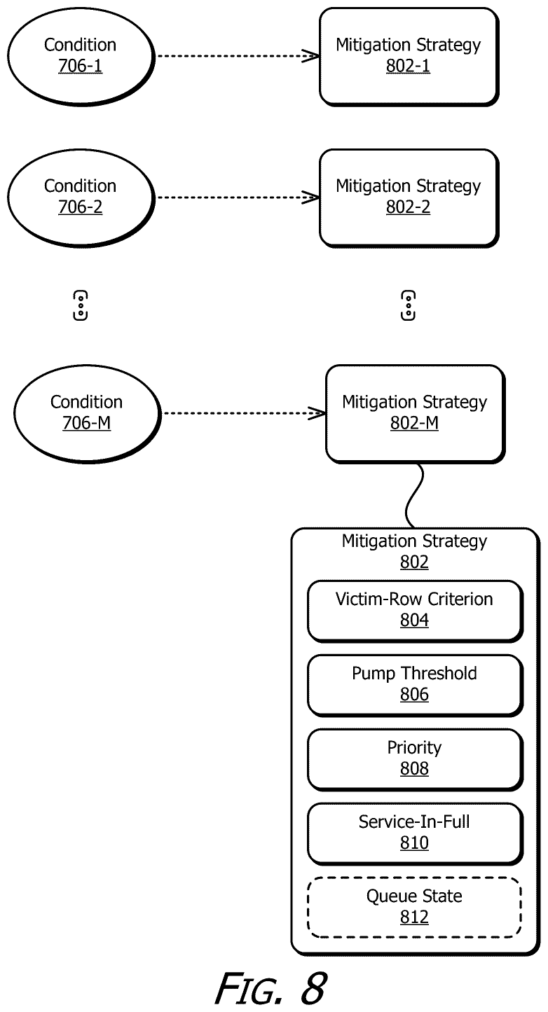

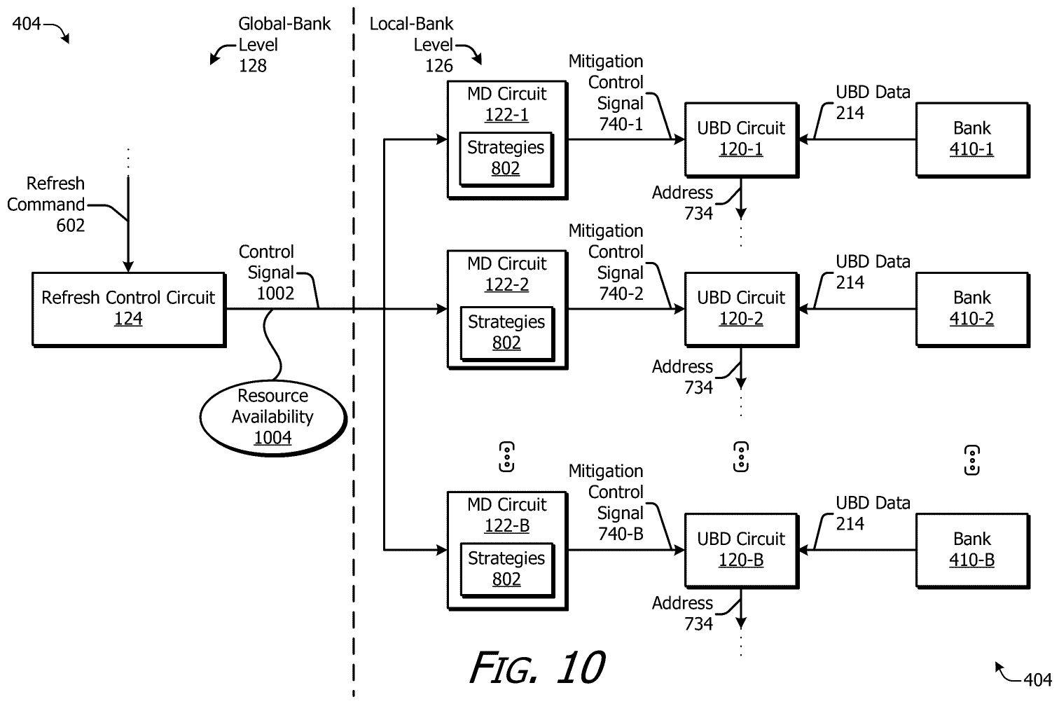

During operation, the selection circuit 736 is controlled by a mitigation control signal 740. The mitigation control signal 740 enables the mitigation decision circuit 122 to control an order in which the various detected conditions 706 are mitigated, as further described with respect to FIG. 10. If the usage-based-disturbance circuit 120 includes a single monitor circuit 702, the mitigation control signal 740 can be provided to the monitor circuit 702 or the mitigation circuit 704 to enable and/or control execution of a mitigation procedure. Each condition 706 can be associated with a particular mitigation strategy, as further described with respect to FIG. 8.

FIG. 8 illustrates example mitigation strategies 802 for different conditions 706 associated with usage-based disturbance. In this example, each condition 706-1, 706-2, and 706-M is associated with a corresponding mitigation strategy 802-1, 802-2, and 802-M. Each mitigation strategy 802 can be associated with a particular type or set of victim rows, which is represented by at least one victim-row criterion 804. The victim-row criterion 804 can be referenced by the victim address calculator 724 (of FIG. 7-1 or 7-2) to determine the appropriate addresses 734 of the victim rows based on a given address 304 of an aggressor row. For example, the victim-row criteria 804 can specify whether the one or more victim rows are to be some combination of the R+1, R−1, R+2, R−2, R+3, or R−3 rows from an identified aggressor row R.

Each mitigation strategy 802 also utilizes a particular quantity of refresh pumps to mitigate the condition 706. This quantity is represented by a pump threshold 806. The pump thresholds 806 for the various mitigation strategies 802-1 to 802-M can be similar or different. Example pump thresholds 806 can be equal to one, two, three, four, five, and so forth. The pump threshold 806 is at least equal to the quantity of victim rows that is determined based on the victim-row criteria 804. In some cases, the pump threshold 806 is greater than the quantity of victim rows. This provides additional timing resources for performing other activities associated with mitigating usage-based disturbance, such as setting the usage-based-disturbance data 214 associated with the aggressor row to a default state to indicate completion of the mitigation procedure.

Consider an example in which the usage-based-disturbance circuit 120 can employ two mitigation strategies 802-1 and 802-2 for mitigating usage-based disturbance associated with two types of conditions 706-1 and 706-2. The first mitigation strategy 802-1 has a first victim-row criteria 804 that identifies victim rows as those that are directly adjacent to the aggressor row (e.g., rows R+1 and R−1). The first pump threshold 806 is set to three. Two of the three refresh pumps 608 are to be used to refresh the two victim rows identified by the first victim-row criteria 804. A remaining one of the three refresh pumps 608 is used to update the usage-based-disturbance data 214 associated with the aggressor row (e.g., set the usage-based-disturbance data 214 to a default value).

The second mitigation strategy 802-2 has a second victim-row criteria 804-2 that identifies victim rows that are proximate to but not directly adjacent to the aggressor row (e.g., rows R+2 and R−2). The second pump threshold 806-2 is set to two such that two refresh pumps 608 are used to refresh the two victim rows identified by the second victim-row criteria 804-2. For this second condition 706-2, the second mitigation strategy 802-2 does not update the usage-based-disturbance data 214 associated with the aggressor row. As such, the second mitigation strategy 802-2 can be performed using fewer refresh pumps 608 compared to the first mitigation strategy 802-1.

The mitigation strategies 802 can also be associated with different priorities 808. The mitigation decision circuit 122 uses the priorities 808 to ensure higher-priority mitigation strategies 802 are executed prior to lower-priority mitigation strategies 802 when resources are available to support this.

Some mitigation strategies 802 may need to be serviced-in-full 810. This means that all actions associated with the pump threshold 806 are to be performed before initiating another mitigation strategy 802. Other mitigation strategies 802 may not need to be service-in-full 810. This means that subsets of the actions associated with a particular mitigation strategy 802 can be interspersed between actions associated with other mitigation strategies 802. These types of mitigation strategies 802 can provide more flexibility in scheduling.

Optionally, in some implementations, one or more mitigation strategies 802 are associated with a state 722 of the corresponding queue 718, as represented by the queue state 812. If the queue state 812 indicates that a queue 718 of a particular monitor circuit 702 is full, then a particular mitigation strategy 802 can be performed to address the queue state 812.

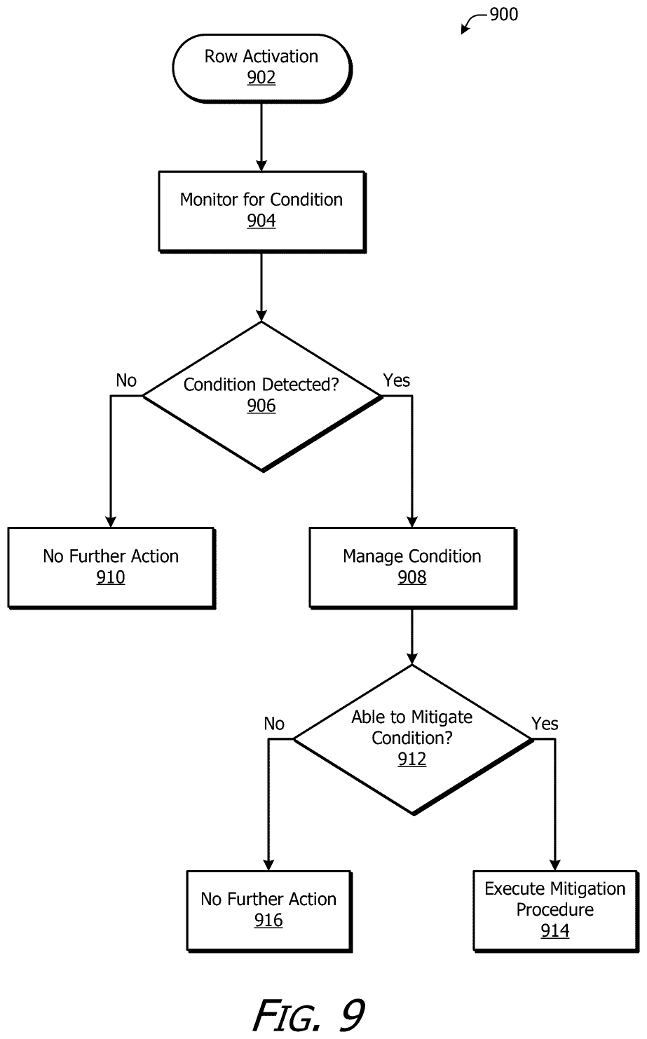

In the example shown in FIG. 8, there is a one-to-one mapping of each condition 706 to a mitigation strategy 802. Other implementations are also possible in which a condition 706 can be associated with multiple mitigation strategies 802. In some cases, a monitor circuit 702 is associated with multiple conditions 706. For example, a monitor circuit 702 can detect a first condition 706 based on the usage-based-disturbance data 214 and can detect a second condition 706 based on the state 722 of the queue 718. In this case, the first condition 706 can be associated with a first mitigation strategy 802 and the second condition 706 can be associated with a second mitigation strategy 802. An operation of the usage-based-disturbance circuit 120 is further described with respect to FIG. 9.

FIG. 9 illustrates an example scheme 900 implemented, at least in part, by the usage-based-disturbance circuit 120. At 902, a row 302 is activated. For example, the memory device 108 activates a row 302 within one of the banks 410 to perform a normal read operation or a normal write operation.

At 904, the usage-based-disturbance circuit 120 monitors for a condition 706 associated with usage-based disturbance. An example operation can include reading the usage-based-disturbance data 214 from the bank 410, updating the usage-based-disturbance data 214, and writing the updated usage-based-disturbance data 214 back to the bank 410. In particular, the operation can include the array counter update (ACU) procedure. The array counter update procedure enables the usage-based-disturbance circuit 120 to keep track of how often a row is activated or accessed since a last refresh. As part of the array counter update procedure, the usage-based-disturbance circuit 120 updates the activation count 308 associated with an activated row 302. More specifically, the usage-based-disturbance circuit 120 reads the activation count 308 that is stored within the activated row 302, increments the activation count 308 using the counter circuit 712 to generate the updated count 726, and writes the updated count 726 back to the activated row 302.

At 906, the usage-based-disturbance circuit 120 determines if (e.g., whether or not) a condition associated with usage-based disturbance is detected. For example, the detection circuit 708 can compare the updated count 726 of the activated row to the mitigation threshold 728, as shown in FIG. 7-1. If the updated count 726 is greater than or equal to the mitigation threshold 728, the usage-based-disturbance circuit 120 detects the condition 706 and proceeds to step 908. Otherwise, if the updated count 726 is less than the mitigation threshold 728, the usage-based-disturbance circuit 120 takes no further action at 910.

At 908, the usage-based-disturbance circuit 120 manages the detected condition 706. For example, the management circuit 710 keeps track of the detected condition 706 using the queue 718. In some cases, the management circuit 710 maintains the entry 720 associated with the detected condition 706 in the queue 718 until the detected condition 706 is mitigated. Sometimes the management circuit 710 may remove and/or replace the entry 720 associated with the detected condition 706 with another entry depending on an operation of the queue 718. In the case that the queue 718 operates in a cyclic manner, the entry can be replaced with a new entry over time. In the case that the queue 718 maintains entries associated with the “worst” conditions, the entry 720 can be replaced by another entry 720 associated with another detected condition 706 that is worse than the previously-detected condition 706 (e.g., with an aggressor row that has a higher activation count 308 than the previous entry 720).

At 912, the mitigation decision circuit 122 determines whether the detected condition 706 can be mitigated. For example, if there are sufficient refresh pumps 608 available for mitigating usage-based disturbance (e.g., the quantity of available refresh pumps 608 is greater or equal to the pump threshold 806), the process continues at 914. Otherwise, the usage-based-disturbance circuit 120 takes no further action at 916.

At 914, the mitigation circuit 704 performs some action associated with the mitigation procedure. In an example implementation, the mitigation circuit 704 determines addresses 734 of the victim rows based on the victim-row criteria 804. The memory device 108 proceeds with refreshing the victim rows specified by the addresses 734.

As explained with respect to FIG. 8, various conditions 706 can trigger usage-based-disturbance mitigation. These conditions 706 may require different mitigation strategies 802 and may be associated with different priorities 808. At the global-bank level 128, the refresh control circuit 124 has information regarding the quantity of refresh pumps 608 that are available for usage-based-disturbance mitigation. This information is not available by default at the local-bank level 126. At the local-bank level 126, however, the mitigation decision circuit 122 has information regarding the priorities 808 of different mitigation strategies 802, which is unknown at the global-bank level 128. Using the techniques for implementing local-bank-level scheduling of usage-based-disturbance mitigation strategies based on global-bank-level control, the memory device 108 can efficiently utilize available timing resources to mitigate usage-based disturbance, as further described with respect to FIG. 10.

FIG. 10 illustrates an example implementation of a die 404 in which aspects of local-bank-level scheduling of usage-based-disturbance mitigation strategies based on global-bank-level control can be performed. Components of the die 404 are associated with either the global-bank level 128, which is depicted on the left side of FIG. 10, or the local-bank level 126, which is depicted on the right side of FIG. 10.

In the depicted configuration, the die 404 includes the refresh control circuit 124, which is implemented at the global-bank level 128. The die 404 also includes multiple banks 410-1, 410-2 . . . 410-B, multiple usage-based-disturbance circuits 120-1, 120-2 . . . 120-B, and multiple mitigation decision circuits 122-1, 122-2 . . . 122-B. The banks 410, the usage-based-disturbance circuits 120, and the mitigation decision circuits 122 are implemented at the local-bank level 126. The usage-based-disturbance circuits 120-1 to 120-B are respectively coupled to the banks 410-1 to 410-B. Also, the mitigation decision circuits 122-1 to 122-B are respectively coupled to the usage-based-disturbance circuits 120-1 to 120-B. The mitigation decision circuits 122-1 to 122-B are also coupled to the refresh control circuit 124.

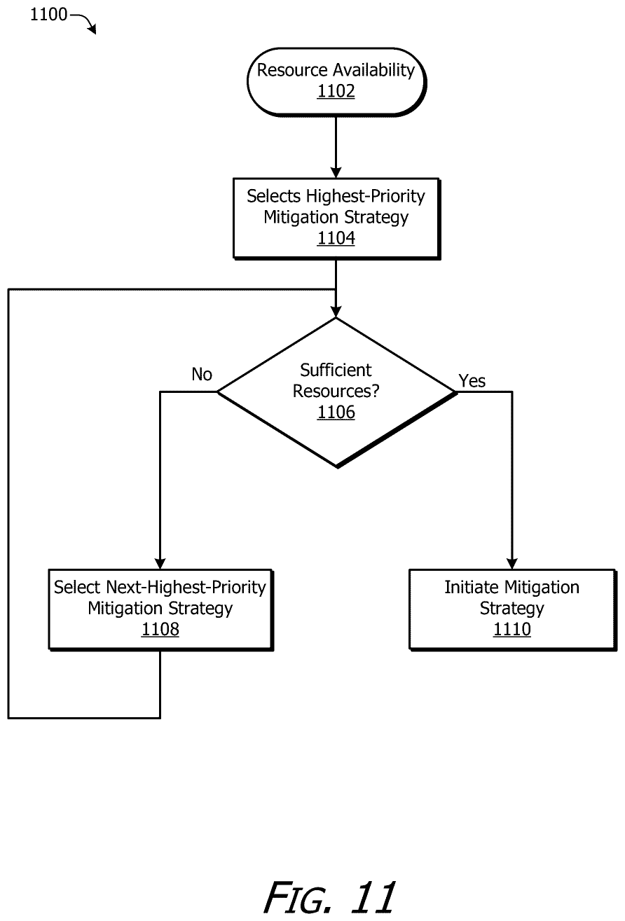

The mitigation decision circuits 122-1 to 122-B each contain information about the mitigation strategies 802 (strategies 802) that can be employed by the corresponding usage-based-disturbance circuits 120-1 to 120-B. In some cases, the mitigation strategies 802 can be provided in a table and arranged in order of the priority 808. This can make it easier for the mitigation decision circuit 122 to loop through the possible mitigation strategies 802 and select a highest-priority mitigation strategy 802 that can be serviced within the available refresh pumps 608, as further described with respect to FIG. 11.

During operation, the usage-based-disturbance circuits 120-1 to 120-B monitor for usage-based disturbance within the corresponding banks 410-1 to 410-B. For example, each usage-based-disturbance circuit 120 can detect an occurrence of one or more conditions 706 associated with usage-based disturbance. This detection process can involve reading the usage-based-disturbance data 214 that is stored within the bank 410, updating the usage-based-disturbance data 214, and writing the updated usage-based-disturbance data 214 back to the bank 410. The usage-based-disturbance circuit 120 can also initiate actions or take steps to support mitigating the condition 706 within the bank 410 when resources are available, as previously described with respect to FIG. 9.

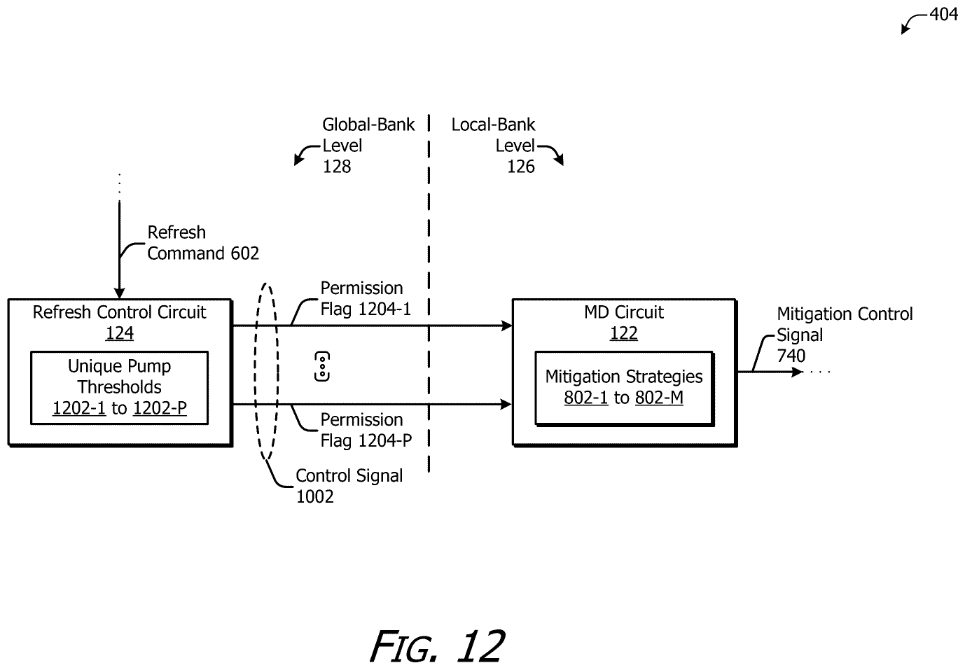

At some point in time, the refresh control circuit 124 receives a refresh command 602. The refresh control circuit 124 can generate the refresh pumps 608 (not shown) based on the refresh command 602. Additionally, the refresh control circuit 124 generates a control signal 1002 to indicate an availability of resources (e.g., resource availability 1004) for mitigating usage-based disturbance. More specifically, the control signal 1002 provides information representing an amount of timing resources that are available for performing usage-based-disturbance mitigation in accordance with the refresh command 602. In an example implementation, the control signal 1002 can include a quantity of refresh pumps 608 that are available for usage-based-disturbance mitigation. As refresh operations are performed, the refresh control circuit 124 can update the resource availability 1004 to indicate a quantity of remaining refresh pumps 608 that are available for usage-based-disturbance mitigation. Other example implementations of the control signal 1002 are also possible and are further described with respect to FIG. 12.

The refresh control circuit 124 passes the control signal 1002 to the mitigation decision circuits 122-1 to 122-B. In some implementations, the refresh control circuit 124 provides the same control signal 1002 to the mitigation decision circuits 122-1 to 122-B. In other implementations, the control signal 1002 can be implemented using multiple control signals 1002, which are provided to different sets of the mitigation decision circuits 122. For example, the refresh control circuit 124 can provide a first control signal 1002 to mitigation decision circuits 122 associated with a first set of banks 410 (e.g., even-numbered banks 410). Also, the refresh control circuit 124 can provide a second control signal 1002 to mitigation decision circuits 122 associated with a second set of banks 410 (e.g., odd-numbered banks 410). This can be advantageous for implementations of the memory device 108 that are capable of performing refresh operations with different timings between different sets of the banks 410.

Each mitigation decision circuit 122-1 to 122-B can enhance scheduling of an operation of its corresponding usage-based-disturbance circuit 120-1 to 120-B based on the resource availability 1004 to prioritize mitigating higher-priority conditions 706 over lower-priority conditions 706. The mitigation decision circuits 122-1 to 122-B can generate respective mitigation control signals 740-1 to 740-B, which cause the corresponding usage-based-disturbance circuits 120-1 to 120-B to initiate mitigation of a particular condition 706. The usage-based-disturbance circuits 120-1 to 120-B can respectively generate addresses 734 of the victim rows to initiate the mitigation procedure. The scheduling-enhancement operations performed by the mitigation decision circuits 122 are further described with respect to FIG. 11.

FIG. 11 illustrates an example scheme 1100 implemented by the mitigation decision circuit 122. At 1102, the mitigation decision circuit 122 receives the resource availability 1004 from the refresh control circuit 124. The resource availability 1004 can indicate an available quantity of refresh pumps 608 for mitigating usage-based disturbance based on a received refresh command 602.

Throughout steps 1104 to 1108, the mitigation decision circuit 122 evaluates the various mitigation strategies 802 in an order of priority 808 and selects the highest-priority mitigation strategy 802 that can be performed with the available resources. In particular, at 1104, the mitigation decision circuit 122 selects a highest-priority mitigation strategy 802. At 1106, the mitigation decision circuit 122 determines if there are sufficient resources to execute the selected mitigation strategy 802. For example, the mitigation decision circuit 122 compares the resource availability 1004 to the pump threshold 806 associated with the selected mitigation strategy 802. If the resource availability 1004 is less than the pump threshold 806, the mitigation decision circuit 122 proceeds to 1108 by selecting a next highest-priority mitigation strategy 1108 to evaluate. Alternatively, if the resource availability 1004 is greater than or equal to the pump threshold 806, the mitigation decision circuit 122 proceeds to 1110.

At 1110, the mitigation decision circuit 122 initiates the selected mitigation strategy 802. For example, the mitigation decision circuit 122 generates a mitigation control signal 740 to cause the usage-based-disturbance circuit 120 to determine the condition at step 912 and proceed to step 914 in FIG. 9. In this case, the usage-based-disturbance circuit 120 generates one or more addresses 734 of victim rows associated with a condition 706 that is mitigated using the selected mitigation strategy 802.

In the examples described with respect to FIGS. 10 and 11, the control signal 1002 provides the resource availability 1004 to the local-bank level 126, and the mitigation decision circuit 122 determines whether or not there are sufficient resources for implementing a particular mitigation strategy 802. Other implementations are also possible in which the logic of the mitigation decision circuit 122 can be simplified by enabling the refresh control circuit 124 to indicate whether or not there are sufficient resources for various pump thresholds 806, as further described with respect to FIG. 12.

FIG. 12 illustrates another example interface between the refresh control circuit 124 and the mitigation decision circuit 122. In contrast to the refresh control circuit 124 of FIG. 12, the refresh control circuit 124 of FIG. 12 includes unique pump thresholds 1202-1 to 1202-P of various mitigation strategies 802-1 to 802-M implemented at the local-bank level 126. The variable P represents a positive integer that is less than or equal to M. In situations in which two or more of the mitigation strategies 802-1 to 802-M have a same pump threshold 806, this pump threshold 806 is represented once in the unique pump thresholds 806-1 to 806-P. With the unique pump thresholds 1202-1 to 1202-P, the refresh control circuit 124 can directly control (or gate) various mitigation strategies 802.

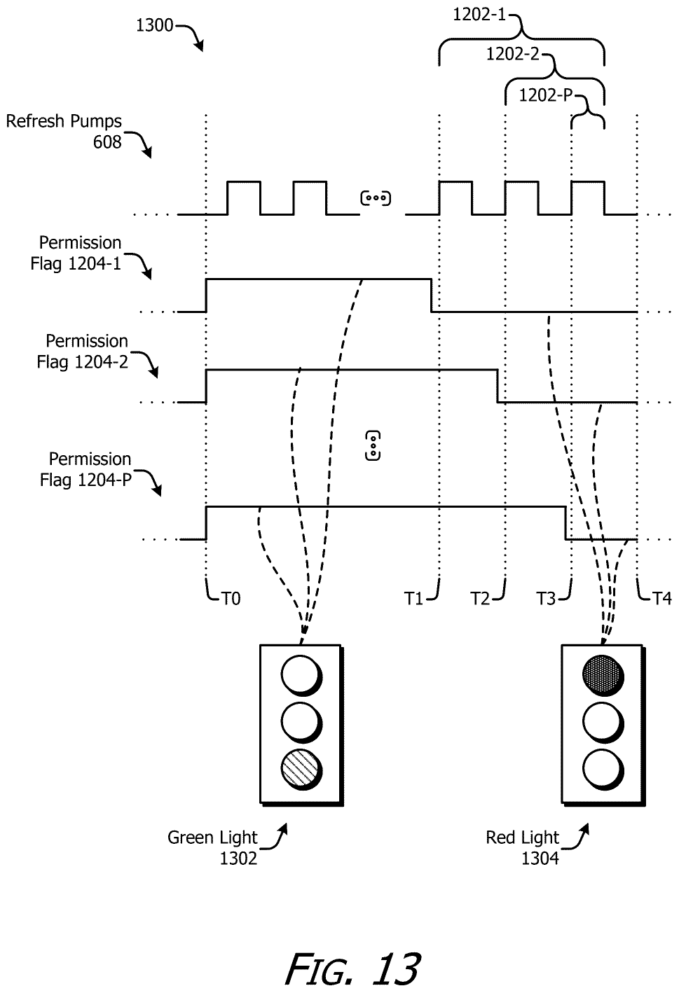

In this example, the refresh control circuit 124 generates multiple permission flags 1204-1 to 1204-P, which represent the control signal 1002 of FIG. 10. The permission flags 1204-1 to 1204-P correspond with the unique pump thresholds 1202-1 to 1202-P. States of the permission flags 1204-1 to 1204-P are determined based on the resource availability 1004. Consider a current refresh command 602 that has a certain quantity of refresh pumps 608 that are waiting to be scheduled and can be used to mitigate usage-based disturbance. In this case, the refresh control circuit 124 communicates to the mitigation decision circuit 122 using the permission flags 1204-1 to 1204-P which of the unique pump thresholds 1202-1 to 1202-P are satisfied by the currently available resources. The mitigation decision circuit 122 can use this information to determine which mitigation strategies 802-1 to 802-M can be serviced. The generating of the permission flags 1204-1 to 1204-P are further described with respect to FIG. 13.

FIG. 13 illustrates an example signal timing diagram 1300. From time T0 to time T4, the refresh control circuit 124 receives a refresh command 602 (not shown) that has a first quantity of refresh pumps 608 available for mitigating usage-based disturbance.

At time T0, no refresh pumps 608 have been scheduled and the quantity of refresh pumps 608 to be scheduled is greater than the unique pump thresholds 1202-1 to 1202-P respectively associated with the permission flags 1204-1 to 1204-P. As such, the refresh control circuit 124 generates the permission flags 1204-1 to 1204-P having a first state (or having a first voltage level) to indicate that the unique pump thresholds 1202-1 to 1202-P are satisfied based on the current resource availability 1004.

After time T0, the refresh pumps 608 are used to perform refreshes. Between time T0 and T1, the remaining quantity of refresh pumps 608 awaiting to be scheduled is greater than the unique pump thresholds 1202-1 to 1202-P. As such, the refresh control circuit 124 continues to generate the permission flags 1204-1 to 1204-P with the first state. In a sense, the refresh control circuit 124 is providing a “green light” 1302 (or multiple green lights 1302) to indicate that there are no resource constraints that impact the scheduling and/or execution of the various mitigation strategies 802-1 to 802-M. During this time interval, the mitigation decision circuit 122 can enhance scheduling of the mitigation strategies 802-1 to 802-M based on the priority 808.

At time T1, the quantity of refresh pumps 608 that has yet to be scheduled is equal to the unique pump threshold 1202-1. Prior to time T1, mitigation strategies 802 having the unique pump threshold 1202-1 associated with the permission flag 1204-1 can be performed. However, after time T1, the resources available for performing this mitigation strategy 802-1 are no longer available. Accordingly, the refresh control circuit 124 generates the permission flag 1204-2 to have a second state (or a second voltage level) to indicate that lack of available resources. A similar situation occurs for permission flag 1204-2 relative to time T2 and for permission flag 1204-P relative to time T3.

Between time T1 and T3, there are some resource constraints that impact the scheduling and/or execution of at least some of the mitigation strategies 802-1 to 802-M. During this time, the refresh control circuit 124 provides a combination of green lights 1302 and “red lights” 1304 using the permission flags 1204-1 to 1204-P. After time T3, all of the permission flags 1204-1 to 1204-P are in the second state. In a sense, the refresh control circuit 124 is providing only red lights 1306 to indicate that there are no resources available to schedule and/or execution the various mitigation strategies 802-1 to 802-M.

As can be seen in FIG. 13, the permission flags 1204-1 to 1204-P are updated in real-time based on the available refresh pumps 608 that are yet to be scheduled. In this way, the refresh control circuit 124 can use the permission flags 1204-1 to 1204-P to directly gate various mitigation strategies 802 that can be employed at the local-bank level 126. The technique for generating the permission flags 1204-1 to 1204-P can be based on relatively simple rules (e.g., a comparison operation).

In some cases, the permission flags 1204 can be implemented as separate signals. In other implementations, the permission flags 1204 can be combined into a single signal and can be represented using different bits. In general, example implementations that utilize the permission flags 1204 can be readily scaled to support increasing quantities of mitigation strategies 802.

With the permission flags 1204, the mitigation decision circuit 122 can be implemented using logic gates, such as AND gates, OR gates, NOR gates, and so forth. For the techniques of implementing local-bank-level scheduling of usage-based-disturbance mitigation strategies based on global-bank-level control, there is no need for the mitigation decision circuit 122 to provide feedback information to the refresh control circuit 124, which reduces the quantity and complexity of signal routing between the global-bank level 128 and the local-bank level 126. Although the example scheduling strategy described above takes into account the pump threshold 806 and the priority 808, other aspects of the mitigation strategies 802 can also be taken into account, such as the service-in-full 810 and/or the queue state 812. In general, the described techniques enable efficient utilization of the available resources while prioritizing higher-priority mitigation strategies 802 whenever resources allow.

### Example Method

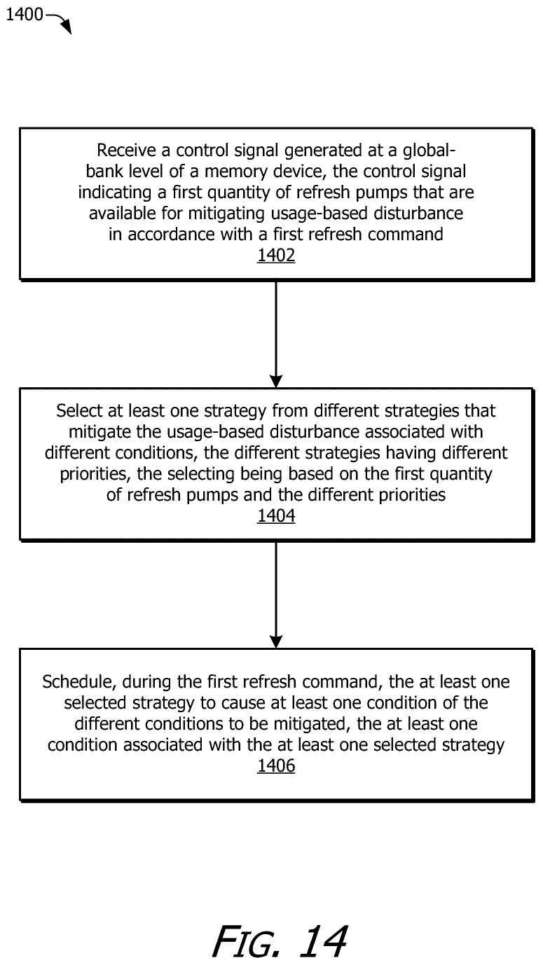

This section describes an example method for implementing aspects of local-bank-level scheduling of usage-based-disturbance mitigation strategies based on global-bank-level control with reference to the flow diagram of FIG. 14. These descriptions may also refer to components, entities, and other aspects depicted in FIGS. 1 to 13 by way of example only. The described method is not necessarily limited to performance by one entity or multiple entities operating on one device.

FIG. 14 illustrates a method 1400, which includes operations 1402 through 1404. In aspects, operations of the method 1400 are implemented by a memory device 108 as described with reference to FIG. 1. In particular, the operations of the method 1400 are performed by the mitigation decision circuit 122 of FIG. 1. At 1402, a control signal that is generated at a global-bank level of a memory device is received. The control signal indicates a first quantity of refresh pumps that are available for mitigating usage-based disturbance in accordance with a first refresh command. For example, the mitigation decision circuit 122 receives the control signal 1002, which is generated by the refresh control circuit 124 at the global-bank level 128, as shown in FIG. 10. The control signal 1002 indicates a resource availability 1004. The resource availability 1004 represents a first quantity of refresh pumps 608 that are available for mitigating usage-based disturbance in accordance with a first refresh command 602, as shown in FIG. 6.

At 1404, at least one strategy from different strategies that mitigate the usage-based disturbance associated with different conditions is selected. The different strategies have different priorities. The selecting is based on the first quantity of refresh pumps and the different priorities. For example, the mitigation decision circuit 122 selects at least one mitigation strategy 802 from different mitigation strategies 802-1 to 802-M. The different mitigation strategies 802-1 to 802-M mitigate the usage-based disturbance associated with different conditions 706-1 to 706-M, as shown in FIG. 8. The different mitigation strategies 802 have different priorities 808. The mitigation decision circuit 122 selects the at least one mitigation strategy 802 based on the first quantity of refresh pumps and the different priorities 808. For example, the mitigation decision circuit 122 selects, from a set of the different mitigation strategies 802-1 to 802-M having pump thresholds 806 that are satisfied by the first quantity of refresh pumps 608, a mitigation strategy 802 that has a highest priority 808. The mitigation decision circuit 122 can also take into account other aspects of the mitigation strategies 802 to make the selection. For instance, the mitigation decision circuit 122 can further consider the service-in-full 810 aspect and/or the queue state 812. Example operations of the mitigation decision circuit 122 for performing this selection are described with respect to FIG. 11.

At 1406, the at least one selected strategy is scheduled, during the first refresh command, to cause at least one condition of the different conditions to be mitigated, the at least one condition is associated with the at least one selected strategy. For example, the mitigation decision circuit 122 schedules, during the first refresh command 602, the at least one selected mitigation strategy 802 to cause the at least one condition 706 associated with the at least one selected mitigation strategy 802 to be mitigated.

In some aspects, the mitigation decision circuit 122 further optimize scheduling of the mitigation strategies 802 to reduce the risk of usage-based disturbance. Consider an example in which the multiple mitigation strategies 802 have pump thresholds 806 that can be serviced using the available resources. In this case, the mitigation decision circuit 122 first schedules one of the multiple mitigation strategies 802 associated with the highest priority 808. The mitigation decision circuit 122 continues scheduling additional mitigation strategies 802 in descending order of priority until the available resources no longer support additional scheduling. In general, the mitigation decision circuit 122 enhances scheduling of the mitigation strategies 802 to efficiently utilize available resources while reducing the risk of usage-based disturbance.

For the figure described above (as well as FIGS. 9 and 11), the order in which operations are shown and/or described are not intended to be construed as a limitation. Any number or combination of the described process operations can be combined or rearranged in any order to implement a given method or an alternative method. Operations may also be omitted from or added to the described methods. Further, described operations can be implemented in fully or partially overlapping manners. Additionally, the processes and the operations thereof across the different methods of FIGS. 9, 11, and 14 may be implemented separately or in conjunction with one another.

Aspects of these methods may be implemented in, for example, hardware (e.g., fixed-circuit circuitry or a processor in conjunction with a memory), firmware, software, or some combination thereof. The method may be realized using one or more of the apparatuses or components shown in FIGS. 1 to 12, the components of which may be further divided, combined, rearranged, and so on. The devices and components of these figures generally represent hardware, such as electronic devices, packaged modules, IC chips, or circuits; firmware or the actions thereof; software; or a combination thereof. Thus, these figures illustrate some of the many possible systems or apparatuses capable of implementing the described methods.

Computer-readable media includes both non-transitory computer storage media and communication media including any medium that facilitates transfer of a computer program (e.g., an application) or data from one entity to another. Non-transitory computer storage media can be any available medium accessible by a computer, such as RAM, ROM, Flash, EEPROM, optical media, and magnetic media.

In the following, various examples for implementing aspects of local-bank-level scheduling of usage-based-disturbance mitigation strategies based on global-bank-level control are described:

Example 1: A memory device comprising:
at least one bank;
a first circuit implemented at a global-bank level of the memory device and configured to:
   receive a first refresh command; and
   generate at least one control signal indicating a first quantity of refresh pumps that are available for mitigating usage-based disturbance based on the first refresh command;
at least one second circuit implemented at a local-bank level of the memory device, the at least one second circuit coupled to the at least one bank and configured to detect, within the at least one bank, different conditions associated with the usage-based disturbance; and
at least one third circuit implemented at the local-bank level of the memory device, the at least one third circuit coupled between the first circuit and the at least one second circuit, the at least one third circuit configured to:
   receive the at least one control signal;
   select at least one strategy from different strategies that mitigate the usage-based disturbance associated with the different conditions, the different strategies having different priorities, the selection based on the first quantity of refresh pumps and based on the different priorities of the different strategies; and
   schedule, during the first refresh command, the at least one selected strategy to cause the at least one second circuit to support mitigation of at least one condition of the different conditions, the at least one condition associated with the at least one selected strategy.

Example 2: The memory device of example 1 or any other example, wherein:
the different conditions comprise:
   a first condition; and
   a second condition;
the different strategies comprise:
   a first strategy associated with the first condition and having a first priority; and
   a second strategy associated with the second condition and having a second priority; and
the at least one third circuit is configured to initiate execution of the first strategy prior to initiating execution of the second strategy based on the first priority being higher than the second priority.

Example 3: The memory device of example 2 or any other example, wherein the at least one third circuit is configured to initiate execution of the first strategy by causing the at least one second circuit to identify an address of a first victim row that is associated with the first condition and that is to be refreshed using a first refresh pump of the first quantity of refresh pumps associated with the first refresh command.

Example 4: The memory device of example 3 or any other example, wherein the at least one third circuit is further configured to cause, in accordance with the first strategy, the at least one second circuit to identify an address of a second victim row that is associated with the first condition and that is to be refreshed using a second refresh pump of the first quantity of refresh pumps associated with the first refresh command.

Example 5: The memory device of example 4 or any other example, wherein:
the at least one second circuit is configured to detect the first condition based on data that is stored in the at least one bank; and
the at least one third circuit is further configured to cause, in accordance with the first strategy, the at least one second circuit to set the data to a default value during a third refresh pump of the first quantity of refresh pumps associated with the first refresh command.

Example 6: The memory device of example 3 or any other example, wherein:
the first circuit is configured to:
   receive a second refresh command; and
   generate the at least one control signal indicating a second quantity of refresh pumps that are available for mitigating the usage-based disturbance based on the second refresh command; and
the at least one third circuit is further configured to cause, in accordance with the first strategy, the at least one second circuit to identify an address of a second victim row that is associated with the first condition and that is to be refreshed using a first refresh pump of the second quantity of refresh pumps associated with the second refresh command.

Example 7: The memory device of example 2 or any other example, wherein the at least one third circuit is configured to enable execution of the first strategy to complete prior to initiating execution of the second strategy.

Example 8: The memory device of example 7 or any other example, wherein:
the first refresh command is associated with a total quantity of refresh pumps that are available for mitigating the usage-based disturbance; and
the first quantity of refresh pumps represents a remaining quantity of refresh pumps that is equal to a difference between the total quantity of refresh pumps and a quantity of refresh pumps that were scheduled between a current time and a start time associated with the first refresh command.

Example 9: The memory device of example 8 or any other example, wherein the at least one third circuit is configured to initiate execution of the second strategy associated with the second condition based on:
completion of the execution of the first strategy; and
the first quantity of refresh pumps being greater than a pump threshold associated with the second strategy, the first quantity of refresh pumps representing the remaining quantity of refresh pumps after the completion of the first strategy.

Example 10: The memory device of example 8 or any other example, wherein:
the first quantity of refresh pumps is less than a pump threshold associated with the second strategy, the first quantity of refresh pumps representing the remaining quantity of refresh pumps after the completion of the first strategy;
the first circuit is configured to:
   receive a second refresh command; and
   generate the at least one control signal indicating a second quantity of refresh pumps that are available for mitigating the usage-based disturbance based on the second refresh command; and
the at least one third circuit is configured to initiate execution of the second strategy associated with the second condition based on:
   a completion of the execution of the first strategy; and
   the second quantity of refresh pumps being greater than the pump threshold associated with the second strategy.

Example 11: The memory device of example 1 or any other example, wherein:
the different strategies are associated with different pump thresholds; and
the at least one third circuit is configured to select the at least one strategy from the different strategies based on the first quantity of refresh pumps, the different priorities, and the different pump thresholds.

Example 12: The memory device of example 11 or any other example, wherein the first circuit is configured to generate the at least one control signal to indicate if each pump threshold of the different pump thresholds is met based on the first quantity of refresh pumps.

Example 13: The memory device of example 1 or any other example, wherein:
the at least one bank comprises multiple banks;
the at least one second circuit comprises multiple second circuits respectively coupled to the multiple banks; and
the at least one third circuit comprises multiple third circuits respectively coupled between the multiple second circuits and the first circuit.

Example 14: A method performed by a circuit implemented at a local-bank level of a memory device, the method comprising:
receiving a control signal generated at a global-bank level of the memory device, the control signal indicating a first quantity of refresh pumps that are available for mitigating usage-based disturbance in accordance with a first refresh command;
selecting at least one strategy from different strategies that mitigate the usage-based disturbance associated with different conditions, the different strategies having different priorities, the selecting being based on the first quantity of refresh pumps and the different priorities; and
scheduling, during the first refresh command, the at least one selected strategy to cause at least one condition of the different conditions to be mitigated, the at least one condition associated with the at least one selected strategy.

Example 15: The method of example 14 or any other example, wherein:
the different strategies are associated with different pump thresholds; and
the method further comprises selecting the at least one strategy based on the first quantity of refresh pumps, the different priorities, and the different pump thresholds.

Example 16: The method of example 14 or any other example, further comprising: initiating execution of a first strategy of the different strategies prior to initiating execution of a second strategy of the different strategies based on the first strategy being associated with a higher priority than the second strategy.

Example 17: The method of example 16 or any other example, further comprising:
enabling execution of the first strategy to complete prior to initiating execution of the second strategy.

Example 18: A memory die comprising:
a circuit implemented at a local-bank level of the memory die and configured to:
   receive a control signal generated at a global-bank level of the memory die, the control signal indicating a first quantity of refresh pumps that are available for mitigating usage-based disturbance in accordance with a first refresh command;
   select at least one strategy from different strategies that mitigate the usage-based disturbance associated with different conditions, the different strategies having different priorities, the selection based on the first quantity of refresh pumps and based on the different priorities of the different strategies; and
   schedule, during the first refresh command, the at least one selected strategy to cause at least one condition of the different conditions to be mitigated, the at least one condition associated with the at least one selected strategy.

Example 19: The memory die of example 18 or any other example, wherein:
the different conditions comprise a first condition and a second condition;
the different strategies comprise:
   a first strategy associated with the first condition and having a first priority; and
   a second strategy associated with the second condition and having a second priority that is lower than the first priority;
the circuit is configured to be connected to a second circuit of the memory die that is implemented at the local-bank level; and
the circuit is configured to generate a second control signal to cause, in accordance with the first strategy, the second circuit to identify a victim row that is associated with the first condition and that is to be refreshed using a first pump of the first quantity of refresh pumps.

Example 20: The memory die of example 18 or any other example, wherein:
the different strategies are associated with different pump thresholds; and
the control signal indicates if each of the different pump thresholds is met based on the first quantity of refresh pumps.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

### CONCLUSION

Although aspects of local-bank-level scheduling of usage-based-disturbance mitigation strategies based on global-bank-level control have been described in language specific to certain features and/or methods, the subject of the appended claims is not necessarily limited to the specific features or methods described. Rather, the specific features and methods are disclosed as a variety of example implementations of local-bank-level scheduling of usage-based-disturbance mitigation strategies based on global-bank-level control.

What is claimed is:

1. A memory device comprising:
at least one bank;
a first circuit implemented at a global-bank level of the memory device and configured to:
receive a first refresh command; and
generate at least one control signal indicating a first quantity of refresh pumps that are available for mitigating usage-based disturbance based on the first refresh command;
at least one second circuit implemented at a local-bank level of the memory device, the at least one second circuit coupled to the at least one bank and configured to detect, within the at least one bank, different conditions associated with the usage-based disturbance; and
at least one third circuit implemented at the local-bank level of the memory device, the at least one third circuit coupled between the first circuit and the at least one second circuit, the at least one third circuit configured to:
receive the at least one control signal;
select at least one strategy from different strategies that mitigate the usage-based disturbance associated with the different conditions, the different strategies having different priorities, the selection based on the first quantity of refresh pumps and based on the different priorities of the different strategies; and
schedule, during the first refresh command, the at least one selected strategy to cause the at least one second circuit to support mitigation of at least one condition of the different conditions, the at least one condition associated with the at least one selected strategy.

2. The memory device of claim 1, wherein:
the different conditions comprise:
a first condition; and
a second condition;
the different strategies comprise:
a first strategy associated with the first condition and having a first priority; and
a second strategy associated with the second condition and having a second priority; and
the at least one third circuit is configured to initiate execution of the first strategy prior to initiating execution of the second strategy based on the first priority being higher than the second priority.

3. The memory device of claim 2, wherein the at least one third circuit is configured to initiate execution of the first strategy by causing the at least one second circuit to identify an address of a first victim row that is associated with the first condition and that is to be refreshed using a first refresh pump of the first quantity of refresh pumps associated with the first refresh command.

4. The memory device of claim 3, wherein the at least one third circuit is further configured to cause, in accordance with the first strategy, the at least one second circuit to identify an address of a second victim row that is associated with the first condition and that is to be refreshed using a second refresh pump of the first quantity of refresh pumps associated with the first refresh command.

5. The memory device of claim 4, wherein:
the at least one second circuit is configured to detect the first condition based on data that is stored in the at least one bank; and
the at least one third circuit is further configured to cause, in accordance with the first strategy, the at least one second circuit to set the data to a default value during a third refresh pump of the first quantity of refresh pumps associated with the first refresh command.

6. The memory device of claim 3, wherein:
the first circuit is configured to:
receive a second refresh command; and
generate the at least one control signal indicating a second quantity of refresh pumps that are available for mitigating the usage-based disturbance based on the second refresh command; and
the at least one third circuit is further configured to cause, in accordance with the first strategy, the at least one second circuit to identify an address of a second victim row that is associated with the first condition and that is to be refreshed using a first refresh pump of the second quantity of refresh pumps associated with the second refresh command.

7. The memory device of claim 2, wherein the at least one third circuit is configured to enable execution of the first strategy to complete prior to initiating execution of the second strategy.

8. The memory device of claim 7, wherein:
the first refresh command is associated with a total quantity of refresh pumps that are available for mitigating the usage-based disturbance; and
the first quantity of refresh pumps represents a remaining quantity of refresh pumps that is equal to a difference between the total quantity of refresh pumps and a quantity of refresh pumps that were scheduled between a current time and a start time associated with the first refresh command.

9. The memory device of claim 8, wherein the at least one third circuit is configured to initiate execution of the second strategy associated with the second condition based on:
completion of the execution of the first strategy; and
the first quantity of refresh pumps being greater than a pump threshold associated with the second strategy, the first quantity of refresh pumps representing the remaining quantity of refresh pumps after the completion of the first strategy.

10. The memory device of claim 8, wherein:
the first quantity of refresh pumps is less than a pump threshold associated with the second strategy, the first quantity of refresh pumps representing the remaining quantity of refresh pumps after the completion of the first strategy;
the first circuit is configured to:
receive a second refresh command; and
generate the at least one control signal indicating a second quantity of refresh pumps that are available for mitigating the usage-based disturbance based on the second refresh command; and
the at least one third circuit is configured to initiate execution of the second strategy associated with the second condition based on:
a completion of the execution of the first strategy; and
the second quantity of refresh pumps being greater than the pump threshold associated with the second strategy.

11. The memory device of claim 1, wherein:
the different strategies are associated with different pump thresholds; and
the at least one third circuit is configured to select the at least one strategy from the different strategies based on the first quantity of refresh pumps, the different priorities, and the different pump thresholds.

12. The memory device of claim 11, wherein the first circuit is configured to generate the at least one control signal to indicate if each pump threshold of the different pump thresholds is met based on the first quantity of refresh pumps.

13. The memory device of claim 1, wherein:
the at least one bank comprises multiple banks;
the at least one second circuit comprises multiple second circuits respectively coupled to the multiple banks; and
the at least one third circuit comprises multiple third circuits respectively coupled between the multiple second circuits and the first circuit.

14. A method performed by a circuit implemented at a local-bank level of a memory device, the method comprising:
receiving a control signal generated at a global-bank level of the memory device, the control signal indicating a first quantity of refresh pumps that are available for mitigating usage-based disturbance in accordance with a first refresh command;
selecting at least one strategy from different strategies that mitigate the usage-based disturbance associated with different conditions, the different strategies having different priorities, the selecting being based on the first quantity of refresh pumps and the different priorities; and
scheduling, during the first refresh command, the at least one selected strategy to cause at least one condition of the different conditions to be mitigated, the at least one condition associated with the at least one selected strategy.

15. The method of claim 14, wherein:
the different strategies are associated with different pump thresholds; and
the method further comprises selecting the at least one strategy based on the first quantity of refresh pumps, the different priorities, and the different pump thresholds.

16. The method of claim 14, further comprising:
initiating execution of a first strategy of the different strategies prior to initiating execution of a second strategy of the different strategies based on the first strategy being associated with a higher priority than the second strategy.

17. The method of claim 16, further comprising:
enabling execution of the first strategy to complete prior to initiating execution of the second strategy.

18. A memory die comprising:
a circuit implemented at a local-bank level of the memory die and configured to:
receive a control signal generated at a global-bank level of the memory die, the control signal indicating a first quantity of refresh pumps that are available for mitigating usage-based disturbance in accordance with a first refresh command;
select at least one strategy from different strategies that mitigate the usage-based disturbance associated with different conditions, the different strategies having different priorities, the selection based on the first quantity of refresh pumps and based on the different priorities of the different strategies; and
schedule, during the first refresh command, the at least one selected strategy to cause at least one condition of the different conditions to be mitigated, the at least one condition associated with the at least one selected strategy.

19. The memory die of claim 18, wherein:
the different conditions comprise a first condition and a second condition;
the different strategies comprise:
a first strategy associated with the first condition and having a first priority; and
a second strategy associated with the second condition and having a second priority that is lower than the first priority;
the circuit is configured to be connected to a second circuit of the memory die that is implemented at the local-bank level; and
the circuit is configured to generate a second control signal to cause, in accordance with the first strategy, the second circuit to identify a victim row that is associated with the first condition and that is to be refreshed using a first pump of the first quantity of refresh pumps.

20. The memory die of claim 18, wherein:
the different strategies are associated with different pump thresholds; and
the control signal indicates if each of the different pump thresholds is met based on the first quantity of refresh pumps.
